(19) United States
(12) Patent Application Publication
(10) Pub. No.: US 2026/0235915 A1
(43) Pub. Date: Aug. 13, 2026

(54) ARRAY SUBSTRATE, DISPLAY PANEL, AND DISPLAY APPARATUS

(71) Applicants: BEIJING BOE DISPLAY TECHNOLOGY CO., LTD., Beijing (CN); BOE TECHNOLOGY GROUP CO., LTD., Beijing (CN)

(72) Inventors: Yihe JIA, Beijing (CN); Tao YU, Beijing (CN); Jiantao LIU, Beijing (CN); Xiangqian DING, Beijing (CN); Kai DIAO, Beijing (CN); Yu MA, Beijing (CN); Xiaopeng CUI, Beijing (CN); Yan YAN, Beijing (CN); Hongming QU, Beijing (CN); Meng LIU, Beijing (CN); Haicheng WANG, Beijing (CN); Xinxin SHAO, Beijing (CN); Yan PANG, Beijing (CN)

(21) Appl. No.: 19/148,988

(22) PCT Filed: Jul. 24, 2024
(86) PCT No.: PCT/CN2024/107363

§ 371 Date: Jul. 17, 2025

(30) Foreign Application Priority Data
Oct. 31, 2023 (CN) 202311435597.8

(51) Int. Cl. G02F 1/1362; G02F 1/1368; H10D 86/40; H10D 86/60

(52) U.S. Cl. CPC G02F 1/13629; G02F 1/1368; H10D 86/443; H10D 86/60

(57) ABSTRACT

An array substrate includes a substrate, a first conductive layer on the substrate, and a second conductive layer on a side of the first conductive layer away from the substrate. The first conductive layer includes gate lines and first data lines. The gate lines extend along a first direction. A first data line in the first data lines includes a plurality of data sub-lines extending along a second direction intersecting the first direction, and the plurality of date sub-lines are arranged at intervals along the second direction. A gate line in the gate lines passes between adjacent data sub-lines and is spaced from the two adjacent data sub-lines. The second conductive layer includes second data lines extending along the second direction. A second data line in the second data lines is connected in parallel to the plurality of data sub-lines included in the first data line.

### CROSS-REFERENCE TO RELATED APPLICATIONS

This application is a national phase entry under 35 USC 371 of International Patent Application No. PCT/CN2024/107363 filed on Jul. 24, 2024, which claims priority to Chinese Patent Application No. 202311435597.8, filed on Oct. 31, 2023, which are incorporated herein by reference in their entirety.

### TECHNICAL FIELD

The present disclosure relates to the field of display technologies, and in particular, to an array substrate, a display panel, and a display apparatus.

### BACKGROUND

Thin film transistor liquid crystal display (TFT-LCD) panels have characteristics such as small size, low power consumption, no radiation, and relatively low manufacturing costs, and hold an important position in the current display panel market.

### SUMMARY

In an aspect, an array substrate is provided. The array substrate includes a substrate, a first conductive layer and a second conductive layer.

The first conductive layer is located on the substrate, and the first conductive layer includes gate lines and first data lines. The gate lines extend along a first direction. A first data line in the first data lines includes a plurality of data sub-lines extending along a second direction, and the plurality of data sub-lines are arranged at intervals along the second direction, the first direction intersecting the second direction. A gate line in the gate lines passes between two adjacent data sub-lines and is spaced from the two adjacent data sub-lines.

The second conductive layer is located on a side of the first conductive layer away from the substrate, and the second conductive layer includes second data lines extending along the second direction. A second data line in the second data lines is connected in parallel to the plurality of data sub-lines included in the first data line.

In some embodiments, the array substrate further includes a plurality of thin film transistors.

The array substrate further includes a semiconductor layer. The semiconductor layer is located between the first conductive layer and the second conductive layer, and the semiconductor layer includes active layer patterns of the plurality of thin film

The second conductive layer further includes source contact portions and drain contact portions, and a source contact portion in the source contact portions and a drain contact portion in the drain contact portions are connected to an active layer pattern in the active layer patterns. A thickness of the source contact portion and a thickness of the drain contact portion are both less than a thickness of the first conductive layer.

In some embodiments, a thickness of the second data line is equal to the thickness of the source contact portion.

In some embodiments, the second data line includes first portions, and a first portion in the first portions of the second data line is disposed opposite to a data sub-line in the plurality of data sub-lines in a direction perpendicular to the substrate; and a thickness of the first portion of the second data line is greater than the thickness of the source contact portion.

In some embodiments, the second data line further includes second portions. Onto the substrate, an orthographic projection of a second portion in the second portions of the second data line intersects an orthographic projection of the gate line and is non-overlapping with orthographic projections of the plurality of data sub-lines. The thickness of the first portion of the second data line is greater than a thickness of the second portion of the second data line.

In some embodiments, the thickness of the second portion of the second data line is equal to the thickness of the source contact portion.

In some embodiments, onto the substrate, orthographic projections of the plurality of data sub-lines included in the first data line at least partially overlap with an orthographic projection of the second data line.

In some embodiments, the array substrate further includes a first insulating layer and first connection portions. The first insulating layer is located between the first conductive layer and the second conductive layer. The first connection portions penetrate the first insulating layer. Two ends of a first connection portion in the first connection portions are connected to a data sub-line in the plurality of data sub-lines and the second data line, respectively.

In some embodiments, onto the substrate, an orthographic projection of the first connection portion is located within a range of at least one of orthographic projections of the data sub-line and the second data line.

In some embodiments, the array substrate further includes a first electrode layer and second connection portions. The first electrode layer is located on a side of the second conductive layer proximate to the substrate, the first electrode layer including pixel electrodes. The second connection portions penetrate the first insulating layer.

The second conductive layer further includes source contact portions and drain contact portions; and for a second connection portion in the second connection portions, one end thereof is connected to a source contact portion in the source contact portions or a drain contact portion in the drain contact portions, and the other end thereof is connected to a pixel electrode in the pixel electrodes.

In some embodiments, the array substrate further includes a first electrode layer, a second electrode layer and third connection portions. The first electrode layer is located on a side of the second conductive layer proximate to the substrate, the first electrode layer including first transfer patterns. A first transfer pattern in the first transfer patterns is connected to a data sub-line in the plurality of data sub-lines. The second electrode layer is located on a side of the second conductive layer away from the substrate, the second electrode layer including second transfer patterns. A second transfer pattern in the second transfer patterns, the second data line and the first transfer pattern are all connected to a third connection portion in the third connection portions.

In some embodiments, the first transfer pattern overlaps and is in contact with the data sub-line.

In some embodiments, the first electrode layer further includes pixel electrodes; the second electrode layer further includes third transfer patterns; and the second conductive layer further includes source contact portions and drain contact portions. A source contact portion in the source contact portions or a drain contact portion in the drain contact portions is connected to a pixel electrode in the pixel electrodes through a third transfer pattern in the third transfer patterns.

In some embodiments, the array substrate further includes a second electrode layer, fourth connection portions and fifth connection portions. The second electrode layer is located on a side of the second conductive layer away from the substrate, the second electrode layer including fourth transfer patterns. A data sub-line in the plurality of data sub-lines is connected to a fourth transfer pattern in the plurality of data sub-lines through a fourth connection portion in the fourth connection portions, and the second data line is connected to the fourth transfer pattern through a fifth connection portion in the fifth connection portions.

In some embodiments, the two adjacent data sub-lines in the second direction are provided therebetween with at least one of the gate lines.

In some embodiments, the array substrate further includes a plurality of thin film transistors, and the first conductive layer includes gate patterns of the plurality of thin film transistors.

The array substrate further includes a first electrode layer, a second electrode layer, a semiconductor layer, and a first insulating layer. The first electrode layer is located on a side of the first conductive layer proximate to the substrate, the first electrode layer including pixel electrodes. The second electrode layer is located on a side of the second conductive layer away from the substrate, the second electrode layer including common electrodes. A pixel electrode in the pixel electrodes is disposed opposite to a common electrode in the common electrodes in a direction perpendicular to the substrate. The semiconductor layer is located between the first conductive layer and the second conductive layer, the semiconductor layer including active layer patterns of the plurality of thin film transistors. The first insulating layer is located between the first conductive layer and the semiconductor layer, the first insulating layer including a first portion and a second portion. The first portion of the first insulating layer is located between the gate patterns and the active layer patterns, and the second portion of the first insulating layer is located between the pixel electrodes and the common electrodes. A thickness of the first portion of the first insulating layer is less than a thickness of the second portion of the first insulating layer.

In some embodiments, the first insulating layer further includes a third portion located between the plurality of data sub-lines and the second data lines. A thickness of the third portion of the first insulating layer is greater than the thickness of the first portion of the first insulating layer.

In some embodiments, the first insulating layer has a first sub-layer and a second sub-layer arranged in a stack. A gate pattern in the gate patterns and an active layer pattern in the active layer patterns have an overlapping region in the direction perpendicular to the substrate, and the overlapping region is non-overlapping with the first sub-layer; and a portion of the second sub-layer is located between the gate patterns and the active layer patterns.

In some embodiments, the first sub-layer is closer to the substrate than the second sub-layer.

In some embodiments, the array substrate further includes a second insulating layer located on a side of the second conductive layer away from the substrate. A thickness of the second insulating layer is greater than or equal to 6,000 angstroms and less than or equal to 9,000 angstroms.

In another aspect, a display panel is provided. The display panel includes the array substrate described in any of the above embodiments, an opposite substrate and a liquid crystal layer. The opposite substrate is disposed opposite to and spaced apart from the array substrate. The liquid crystal layer is disposed between the array substrate and the opposite substrate.

In yet another aspect, a display apparatus is provided. The display apparatus includes the display panel described in any of the above embodiments and a driving chip. The driving chip is electrically connected to the display panel.

### BRIEF DESCRIPTION OF THE DRAWINGS

In order to describe technical solutions in the present disclosure more clearly, the accompanying drawings to be used in some embodiments of the present disclosure will be introduced briefly. It is apparent that the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a plan view showing a structure of a display panel, in accordance with some embodiments;

FIG. 3A is a plan view showing a structure of a sub-pixel, in accordance with some embodiments;

FIG. 3B is another plan view showing a structure of a sub-pixel, in accordance with some embodiments;

FIG. 4A is a plan view showing a structure of a local region of a display panel, in accordance with some embodiments;

FIG. 4B is another plan view showing a structure of a local region of a display panel, in accordance with some embodiments;

FIG. 5 is a structural diagram of a display panel, in accordance with some embodiments;

FIG. 6 is a cross-sectional view of a local region of an array substrate, in accordance with some embodiments;

FIG. 7A is a plan view showing a structure of a local region of an array substrate, in accordance with some embodiments;

FIG. 7B is another plan view showing a structure of a local region of an array substrate, in accordance with some embodiments;

FIG. 8 is a cross-sectional view of the array substrate shown in FIG. 7A taken along the section line B-B or the array substrate shown in FIG. 7B taken along the section line C-C;

FIG. 9 is a plan view showing structures of a data sub-line in a first conductive layer, a second data line in a second conductive layer, and a fourth transfer pattern in a second electrode layer, in accordance with some embodiments;

FIG. 10A is yet another plan view showing a structure of a local region of an array substrate, in accordance with some embodiments;

FIG. 10B is still another plan view showing a structure of a local region of an array substrate, in accordance with some embodiments;

FIG. 10C is a cross-sectional view of the array substrate shown in FIG. 10A taken along the section line D-D or the array substrate shown in FIG. 10B taken along the section line E-E;

FIG. 11A is still yet another plan view showing a structure of a local region of an array substrate, in accordance with some embodiments;

FIG. 11B is still yet another plan view showing a structure of a local region of an array substrate, in accordance with some embodiments;

FIG. 11C is a cross-sectional view of the array substrate shown in FIG. 11A taken along the section line F-F or the array substrate shown in FIG. 11B taken along the section line G-G;

FIG. 12 is a cross-sectional view of the array substrate shown in FIG. 10A taken along the section line H-H or the array substrate shown in FIG. 10B taken along the section line I-I;

FIG. 13 is a cross-sectional view of the array substrate shown in FIG. 11A taken along the section line J-J or the array substrate shown in FIG. 11B taken along the section line K-K;

FIG. 14 is another cross-sectional view of a local region of an array substrate, in accordance with some embodiments;

FIG. 15 is yet another cross-sectional view of a local region of an array substrate, in accordance with some embodiments;

FIG. 16 is still another cross-sectional view of a local region of an array substrate, in accordance with some embodiments; and

FIG. 17 is still yet another cross-sectional view of a local region of an array substrate, in accordance with some embodiments.

### DETAILED DESCRIPTION

The technical solutions in some embodiments of the present disclosure will be described clearly and completely below with reference to the accompanying drawings. It is apparent that the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the terms “first” and “second” are only used for descriptive purposes, and are not to be construed as indicating or implying the relative importance or implicitly indicating the number of indicated technical features. Thus, features defined by “first” or “second” may explicitly or implicitly include one or more of the features. In the description of the embodiments of the present disclosure, the term “a plurality of” or “multiple” means two or more unless otherwise specified.

In the description of some embodiments, the expressions “coupled,” “connected,” and derivatives thereof may be used. The term “connected” should be understood in a broad sense. For example, the term “connected” may represent a fixed connection, a detachable connection, or a one-piece connection, or may represent a direct connection, or may represent an indirect connection through an intermediate medium. The term “coupled” indicates, for example, that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the content herein.

The phrase “at least one of A, B, and C” has the same meaning as the phrase “at least one of A, B, or C,” both including the following combinations of A, B, and C, only A, only B, only C, a combination of A and B, a combination of A and C, a combination of B and C, and a combination of A, B, and C.

The phrase “A and/or B” includes the following three combinations: only A, only B, and a combination of A and B.

As used herein, the term “if” is, optionally, construed as “when” or “in a case where” or “in response to determining that” or “in response to detecting,” depending on the context. Similarly, depending on the context, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event].”

The use of “applicable to” or “configured to” herein means an open and inclusive expression, which does not exclude devices that are applicable to or configured to perform additional tasks or steps.

Additionally, the use of the phrase “based on” is meant to be open and inclusive, since a process, step, calculation or other action that is “based on” one or more of the stated conditions or values may, in practice, be based on additional conditions or value beyond those stated.

The term such as “about,” “substantially,” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be that, for example, a difference between the two that are equal is less than or equal to 5% of either of the two.

It should be understood that when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views that are schematic illustrations of idealized embodiments. In the accompanying drawings, thickness of layers and sizes of regions/areas are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including deviations due to, for example, manufacturing. For example, an etched region shown as a rectangular shape generally has a curved feature. Therefore, the regions shown in the accompanying drawings are schematic in nature, and their shapes are not intended to show actual shapes of regions in devices, and are not intended to limit the scope of the exemplary embodiments.

For ease of description in the following, an XYZ coordinate system is defined, in which a third direction Z is perpendicular to a substrate, an XY plane is perpendicular to the Z direction, and a first direction X intersects a second direction Y. For example, the first direction X is perpendicular to the second direction Y.

It will be noted that expressions shown in the accompanying drawings of the present disclosure have the following meanings, for example, “211/21” indicates that a component 211 belongs to a component 21, for example, “51(5)” indicates that a component 51 is located in a film layer 5, and other similar reference marks shown in the accompanying drawings are used in the same manner as described above.

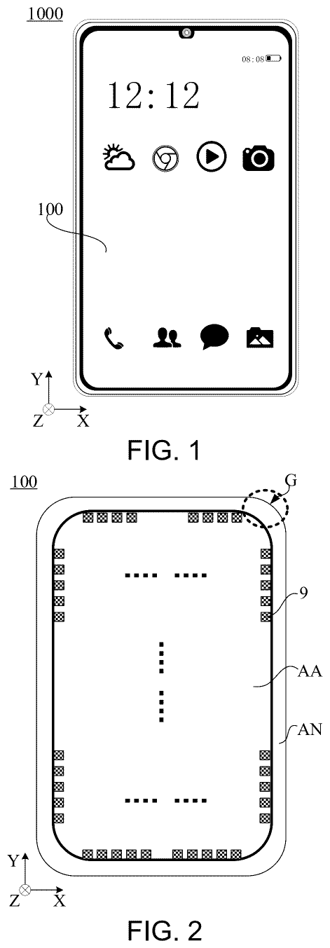

As shown in FIG. 1, some embodiments of the present disclosure provide a display apparatus 1000.

For example, the display apparatus 1000 may be any apparatus capable of displaying images whether in motion (e.g., videos) or stationary (e.g., static images), and whether literal or graphical. More specifically, it is expected that the embodiments may be implemented in or associated with various electronic devices, which include (but are not limited to), for example, a mobile phone, a wireless device, a personal digital assistant (PDA), a hand-held or portable computer, a GPS receiver/navigator, a camera, an MP4 video player, a video camera, a game console, a watch, a clock, a calculator, a TV monitor, a flat panel display, a computer monitor, a car display (e.g., an odometer display), a navigator, a cockpit controller and/or display, a display in camera view (e.g., a display for a rear camera in a vehicle), an electronic photo, an electronic billboard or indicator, a projector, building structures, packaging and aesthetic structure (e.g., a display for an image of a piece of jewelry), and the like. FIG. 1 illustrates an example where the display apparatus 1000 is a mobile phone.

For example, the display apparatus 1000 may be a thin film transistor liquid crystal display (TFT-LCD) apparatus.

In some embodiments, with continuous reference to FIG. 1, the display apparatus 1000 includes a display panel 100 and a driving chip (not shown in the figure). The driving chip is electrically connected to the display panel 100 and is configured to drive the display panel 100 to display images.

For example, the driving chip in the display apparatus 1000 may be a source driving chip (Source Driver IC).

For example, the driving chip in the display apparatus 1000 may be packaged using methods such as chip on film (COF), chip on glass (COG), or chip on PI (COP), and bonded to the display panel 100.

For example, the driving chip in the display apparatus 1000 may be packaged by chip on film (COF). In a case where the driving chip in the display apparatus 1000 is packaged by chip on film (COF), the display apparatus 1000 includes a COF assembly. The COF assembly may include a flexible printed circuit (FPC) and the driving chip bonded to the flexible printed circuit (FPC).

In some embodiments, the display apparatus 1000 may further include an optical element (not shown in the figure).

For example, the optical element may include a camera, enabling the display apparatus 1000 to implement various functions such as taking photos, recording videos, and recognizing faces.

The optical element may further include a sensor, etc. For example, the optical element may include an under-screen fingerprint recognition sensor, enabling the display apparatus 1000 to implement fingerprint recognition and other functions. As another example, the optical element may include an infrared sensor.

The above display panel 100 will be described in detail below.

FIG. 2 is a plan view showing a structure of the display panel 100 in accordance with some embodiments. In some embodiments, as shown in FIG. 2, the display panel 100 may be of a rectangular structure.

It will be noted that the “rectangular structure” referred to above means that a boundary of the display panel 100 is in the shape of a rectangle as a whole, but is not limited to a standard rectangle. That is, the term “rectangle” here not only includes the shape of a standard rectangle, but also, in consideration of process conditions, includes shapes similar to a rectangle. For example, as shown in FIG. 2, long sides and short sides of the rectangle are curved at each intersection position (i.e., corners G), that is, the corners G are smooth, enabling the boundary of the display panel 100 to be a rounded rectangle in the plan view.

In some other embodiments, the display panel 100 may be a circular structure or in any of other shapes with corners.

Some embodiments of the present disclosure will be illustratively described below by taking an example where the display panel 100 is of a rectangular structure, but the embodiments of the present disclosure are not limited thereto, and the display panel 100 may be in any of other shapes.

In some embodiments, with continuous reference to FIG. 2, the display panel 100 includes a display area AA for displaying images and a peripheral area AN located on at least one side of the display area AA.

For example, the peripheral area AN of the display panel 100 may be located on one side of the display area AA of the display panel 100.

Alternatively, the peripheral area AN of the display panel 100 may be located on opposite sides of the display area AA of the display panel 100.

Alternatively, with continuous reference to FIG. 2, the peripheral area AN of the display panel 100 may surround the display area AA of the display panel 100.

It will be noted that the specific arrangement of the peripheral area AN of the display panel 100 is related to the specific design of the display panel 100, which may be designed depending on actual needs. Some embodiments of the present disclosure will be illustratively described below by taking an example where the peripheral area AN of the display panel 100 surrounds the display area AA of the display panel 100.

For example, the peripheral area AN of the display panel 100 may be provided therein with a gate driving circuit (such as a gate driver on array, GOA for short) and control signal lines (such as clock signal lines and power supply voltage signal lines). Of course, the functions of the peripheral area AN of the display panel 100 include but are not limited to the above.

In some embodiments, with continuous reference to FIG. 2, the display area AA of the display panel 100 is provided therein with a plurality of sub-pixels 9, in order to implement the image display function of the display panel 100, where the sub-pixels 9 are each the smallest light-emitting unit in the display area AA.

For example, the plurality of sub-pixels 9 in the display area AA of the display panel 100 may emit light of a same color. In a case where the plurality of sub-pixels 9 in the display area AA of the display panel 100 emit light of the same color, the display panel 100 further includes a color filter layer disposed on a light exit side of the plurality of sub-pixels 9. For example, the plurality of sub-pixels 9 in the display area AA all emit light of one color, e.g., emit white light, red light, green light, or blue light. In this case, after passing through the color filter layer, light of one color emitted by a sub-pixel 9 in the display area AA is kept as light of the same color or converted into light of another color, and then directed out. Thus, when the plurality of sub-pixels 9 in the display area AA of the display panel 100 emit light of the same color, the display area AA of the display panel 100 can implement multi-color light emission.

For example, with continuous reference to FIG. 2, the plurality of sub-pixels 9 in the display area AA of the display panel 100 may be arranged in an array.

For example, with continuous reference to FIG. 2, the plurality of sub-pixels 9 in the display area AA of the display panel 100 may be arranged in intervals along both a first direction X and a second direction Y. The first direction X may be a row direction in which the plurality of sub-pixels 9 are arranged in the display area AA, and the second direction Y may be a column direction in which the plurality of sub-pixels 9 are arranged in the display area AA.

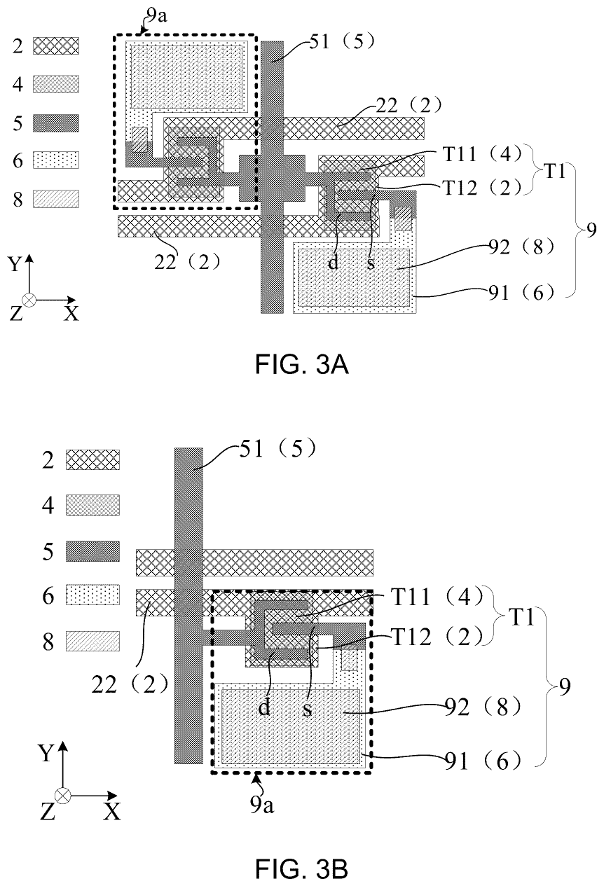

FIG. 3A and FIG. 3B are each a plan view showing a structure of the sub-pixel 9 in accordance with some embodiments. In some embodiments, as shown in FIG. 3A and FIG. 3B, in a case where the display apparatus 1000 is a thin film transistor liquid crystal display (TFT-LCD) apparatus, the display panel 100 in the display apparatus 1000 is a thin film transistor liquid crystal display (TFT-LCD) panel, and the sub-pixel 9 in the display area AA of the display panel 100 may include a pixel electrode 91 and a common electrode 92. The pixel electrode 91 and the common electrode 92 are disposed opposite to each other in the third direction Z, and the pixel electrode 91 and the common electrode 92 may form a pixel capacitance.

For example, a material of the pixel electrode 91 may include a transparent conductive material. For example, the material of the pixel electrode 91 may include indium tin oxide (ITO), indium zinc oxide (IZO), or the like.

A material of the common electrode 92 may also include a transparent conductive material. For example, the material of the common electrode 92 may include indium tin oxide (ITO), indium zinc oxide (IZO), or the like.

In some embodiments, with continuous reference to FIG. 3A and FIG. 3B, the sub-pixel 9 in the display area AA of the display panel 100 may further include a thin film transistor (TFT) T1. The thin film transistor T1 includes an active layer pattern T11 and a gate pattern T12, and the active layer pattern T11 and the gate pattern T12 of the thin film transistor T1 are disposed opposite to each other in the third direction Z.

The active layer pattern T11 of the thin film transistor T1 includes a source region and a drain region, as well as a channel region located between the source region and the drain region.

For example, with continuous reference to FIG. 3A and FIG. 3B, the active layer pattern T11 of the thin film transistor T1 may be connected to a source contact portion s and a drain contact portion d. Specifically, the source region of the active layer pattern T11 of the thin film transistor T1 may be connected to the source contact portion s, and the drain region of the active layer pattern T11 of the thin film transistor T1 may be connected to the drain contact portion d.

For example, the thin film transistor T1 in the sub-pixel 9 may be a low temperature polysilicon thin film transistor or an oxide thin film transistor. An active layer of the low temperature polysilicon thin film transistor is made of low temperature polysilicon (LTPS), and an active layer of the oxide thin film transistor is made of an oxide semiconductor (Oxide). The low temperature polysilicon thin film transistor has advantages such as high mobility and fast charging, and the oxide thin film transistor has advantages such as low leakage current.

For example, the thin film transistor T1 in the sub-pixel 9 may be an N-type transistor or a P-type transistor.

In some embodiments, with continuous reference to FIG. 3A and FIG. 3B, the display panel 100 further includes second data lines 51 and gate lines 22. The gate lines 22 extend along the first direction X, and second data lines 51 extend along the second direction Y.

The first direction X and the second direction Y intersect, that is to say, the gate lines 22 extending along the first direction X cross the second data lines 51 extending along the second direction Y. The gate lines 22 and the second data lines 51 together define a plurality of pixel regions 9a, and the sub-pixels 9 in the display panel 100 may be each located in a pixel region 9a (for example, the thin film transistor T1, the pixel electrode 91 and the common electrode 92 in the sub-pixel 9 are located in the pixel region 9a).

With continuous reference to FIG. 3A and FIG. 3B, in a case where the thin film transistor T1 in the sub-pixel 9 is an N-type transistor, the drain region of the active layer pattern T11 of the thin film transistor T1 is connected to a second data line 51, and the source region of the active layer pattern T11 of the thin film transistor T1 is connected to a pixel electrode 91. The gate pattern T12 of the thin film transistor T1 is connected to a gate line 22.

For example, in a case where the thin film transistor T1 in the sub-pixel 9 is an N-type transistor, the drain region of the active layer pattern T11 of the thin film transistor T1 may be connected to the second data line 51 through the drain contact portion d, and the source region of the active layer pattern T11 of the thin film transistor T1 may be connected to the pixel electrode 91 through the source contact portion s.

In a case where the thin film transistor T1 in the sub-pixel 9 is a P-type transistor, the source region of the active layer pattern T11 of the thin film transistor T1 is connected to a second data line 51, and the drain region of the active layer pattern T11 of the thin film transistor T1 is connected to a pixel electrode 91. The gate pattern T12 of the thin film transistor T1 is connected to a gate line 22.

For example, in a case where the thin film transistor T1 in the sub-pixel 9 is a P-type transistor, the source region of the active layer pattern T11 of the thin film transistor T1 may be connected to the second data line 51 through the source contact portion s, and the drain region of the active layer pattern T11 of the thin film transistor T1 may be connected to the pixel electrode 91 through the drain contact portion d.

Some embodiments of the present disclosure will be illustratively described below by taking an example where the thin film transistor T1 in the sub-pixel 9 is an N-type transistor. However, the embodiments of the present disclosure are not limited to the above, and the thin film transistor T1 in the sub-pixel 9 may alternatively be a P-type transistor.

With continuous reference to FIG. 3A and FIG. 3B, the gate line 22 can control the thin film transistor T1 in the sub-pixel 9 to be turned on or off. When the thin film transistor T1 in the sub-pixel 9 is turned on, the second data line 51 can charge the pixel electrode 91 through the thin film transistor T1.

In some embodiments, with continuous reference to FIG. 3B, the display panel 100 may adopt a single gate line structure. In the display panel 100 with the single gate line structure, the plurality of gate lines 22 in the display panel 100 are in one-to-one correspondence with multiple rows of sub-pixels 9 (i.e., the plurality of sub-pixels 9 arranged along the first direction X), that is, each gate line 22 in the display panel 100 corresponds to one row of sub-pixels 9 (i.e., multiple sub-pixels 9 arranged along the first direction X); and the plurality of second data lines 51 in the display panel 100 are in one-to-one correspondence with multiple columns of sub-pixels 9 (i.e., the plurality of sub-pixels 9 arranged along the second direction Y), that is, each second data line 51 in the display panel 100 corresponds to one column of sub-pixels 9 (i.e., multiple sub-pixels 9 arranged along the second direction Y).

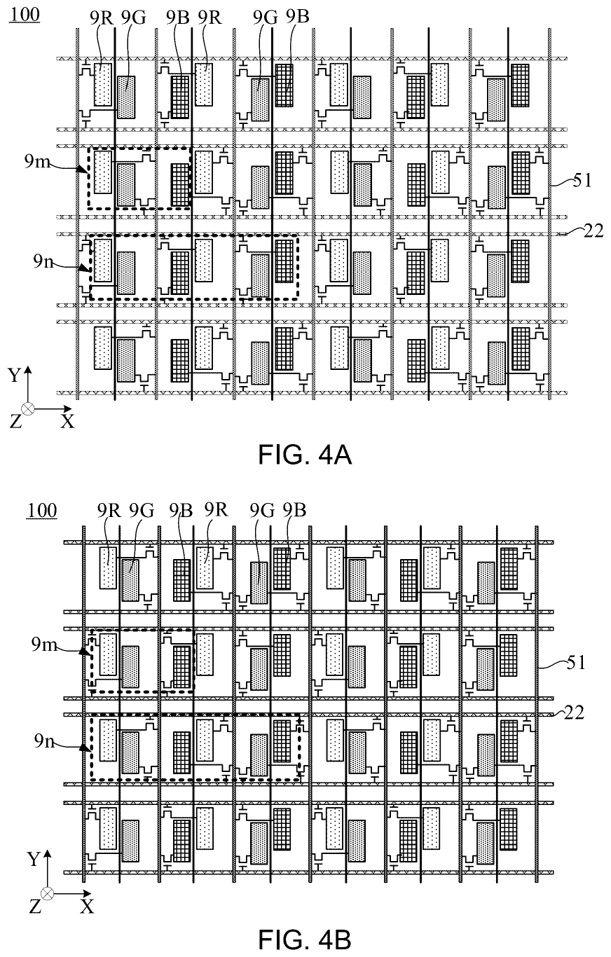

FIG. 4A and FIG. 4B are each a plan view showing a structure of a local region of the display panel 100 in accordance with some embodiments. In some other embodiments, with continuous reference to FIG. 3A, and in combination with FIG. 4A and FIG. 4B, the display panel 100 may adopt a dual gate line structure. In the display panel 100 with the dual gate line structure, each row of sub-pixels 9 (i.e., multiple sub-pixels 9 arranged along the first direction X) corresponds to two gate lines 22 in the display panel 100, and each second data line 51 in the display panel 100 corresponds to two columns of sub-pixels 9 (i.e., multiple sub-pixels 9 arranged along the second direction Y).

With continuous reference to FIG. 3A and FIG. 3B, and in combination with FIG. 4A and FIG. 4B, compared to the display panel 100 with the single gate line structure, the number of the gate lines 22 corresponding to each row of sub-pixels 9 (i.e., multiple sub-pixels 9 arranged along the first direction X) in the display panel 100 with the dual gate line structure is twice the number of the gate line 22 corresponding to each row of sub-pixels 9 (i.e., multiple sub-pixels 9 arranged along the first direction X) in the display panel 100 with the single gate line structure; and two columns of sub-pixels 9 (i.e., multiple sub-pixels 9 arranged along the second direction Y) in the display panel 100 with the dual gate line structure correspond to a same second data line 51, and each column of sub-pixels 9 (i.e., multiple sub-pixels 9 arranged along the second direction Y) in the display panel 100 with the single gate line structure corresponds to a respective second data line 51.

That is to say, the use of the dual gate line structure in the display panel 100 may reduce the number of the second data lines 51 in the display panel 100, thereby reducing the cost of the driving chip and reducing the fan-out wiring space, so as to reduce the size of the peripheral area AN of the display panel 100, which is conducive to realizing a narrow frame design of the display panel 100.

For example, with continuous reference to FIG. 4A, and in combination with FIG. 3A, in a case where the display panel 100 adopts the dual gate line structure, two gate lines 22 corresponding to one row of sub-pixels 9 (i.e., multiple sub-pixels 9 arranged along the first direction X) in the display panel 100 are located on opposite sides of the row of sub-pixels 9 (i.e., the multiple sub-pixels 9 arranged along the first direction X) along the second direction Y.

For two gate lines 22 corresponding to one row of sub-pixels 9 (i.e., multiple sub-pixels 9 arranged along the first direction X) in the display panel 100, one gate line 22 is connected to thin film transistors T1 of some of the sub-pixels 9 in this row (i.e., the multiple sub-pixels 9 arranged along the first direction X), and the other gate line 22 is connected to thin film transistors T1 of the rest of the sub-pixels 9 in this row (i.e., the multiple sub-pixels 9 arranged along the first direction X).

For example, with continuous reference to FIG. 4A, and in combination with FIG. 3A, each row of sub-pixels 9 (i.e., multiple sub-pixels 9 arranged along the first direction X) includes multiple pixel units 9m, with each pixel unit 9m including three sub-pixels 9 (specifically, the three sub-pixels 9 included in each pixel unit 9m may be a first sub-pixel 9R, a second sub-pixel 9G and a third sub-pixel 9B). In one row of sub-pixels 9 (i.e., multiple sub-pixels 9 arranged along the first direction X), two adjacent pixel units 9m may form a pixel unit group 9n. For two gate lines 22 corresponding to one row of sub-pixels 9 (i.e., multiple sub-pixels 9 arranged along the first direction X) in the display panel 100, one gate line 22 may be connected to a thin film transistor T1 in the 1^{st} sub-pixel 9 (i.e., a first sub-pixel 9R), a thin film transistor T1 in the 4^{th} sub-pixel 9 (i.e., another first sub-pixel 9R), and a thin film transistor T1 in the 6^{th} sub-pixel 9 (i.e., a third sub-pixel 9B), which are in the pixel unit group 9n, and the other gate line 22 may be connected to a thin film transistor T1 in the 2^{nd} sub-pixel 9 (i.e., a second sub-pixel 9G), a thin film transistor T1 in the 3^{rd} sub-pixel 9 (i.e., another third sub-pixel 9B), and a thin film transistor T1 in the 5^{th} sub-pixel 9 (i.e., another second sub-pixel 9G), which are in the pixel unit group 9n.

For example, with continuous reference to FIG. 4A, and in combination with FIG. 3A, in a case where the display panel 100 adopts the dual gate line structure, one second data line 51 is arranged for every two columns of sub-pixels 9 (i.e., multiple sub-pixels 9 arranged along the second direction Y). The j-th second data line 51 may be connected to thin film transistors T1 in the (2j-1)-th column of sub-pixels 9 and the 2j-th column of sub-pixels 9 in the odd-numbered rows of sub-pixels 9 (i.e., multiple sub-pixels 9 arranged along the first direction X), and the j-th second data line 51 may further be connected to thin film transistors T1 in the (2j-3)-th column of sub-pixels 9 and the (2j-2)-th column of sub-pixels 9 in the even-numbered rows of sub-pixels 9 (i.e., multiple sub-pixels 9 arranged along the first direction X), where j takes a value from 1 (j≥1), and j is a positive integer.

It will be noted that when j takes a value of 1 (j=1), since there are no (2j-3)-th and (2j-2)-th columns of sub-pixels 9 in the display panel 100 in this case, the 1^{st} second data line 51 is not connected to the even-numbered rows of sub-pixels 9 (i.e., multiple sub-pixels 9 arranged along the first direction X).

For example, with continuous reference to FIG. 4A, and in combination with FIG. 3A, the 2^{nd} second data line 51 may be connected to thin film transistors T1 in the third and fourth columns of sub-pixels 9 in the odd-numbered rows of sub-pixels 9 (i.e., multiple sub-pixels 9 arranged along the first direction X), and the 2^{nd} second data line 51 may further be connected to thin film transistors T1 in the first and second columns of sub-pixels 9 in the even-numbered rows of sub-pixels 9 (i.e., multiple sub-pixels 9 arranged along the first direction X).

Alternatively, with continuous reference to FIG. 4B, and in combination with FIG. 3A, in a case where the display panel 100 adopts the dual gate line structure, one second data line 51 is arranged for every two columns of sub-pixels 9 (i.e., multiple sub-pixels 9 arranged along the second direction Y). The j-th second data line 51 may be connected to thin film transistors T1 in the (2j-3)-th column of sub-pixels 9 and the (2j-2)-th column of sub-pixels 9 in the odd-numbered rows of sub-pixels 9 (i.e., multiple sub-pixels 9 arranged along the first direction X), and the j-th second data line 51 may further be connected to thin film transistors T1 in the (2j-1)-th column of sub-pixels 9 and the 2j-th column of sub-pixels 9 in the even-numbered rows of sub-pixels 9 (i.e., multiple sub-pixels 9 arranged along the first direction X), where j takes a value from 1 (j≥1), and j is a positive integer.

It will be noted that when j takes a value of 1 (j=1), since there are no (2j-3)-th and (2j-2)-th columns of sub-pixels 9 in the display panel 100 in this case, the 1^{st} second data line 51 is not connected to the odd-numbered rows of sub-pixels 9 (i.e., multiple sub-pixels 9 arranged along the first direction X).

For example, with continuous reference to FIG. 4B, and in combination with FIG. 3A, the 2^{nd} second data line 51 may be connected to thin film transistors T1 in the first and second columns of sub-pixels 9 in the odd-numbered rows of sub-pixels 9 (i.e., multiple sub-pixels 9 arranged along the first direction X), and the 2^{nd} second data line 51 may further be connected to thin film transistors T1 in the third and fourth columns of sub-pixels 9 in the even-numbered rows of sub-pixels 9 (i.e., multiple sub-pixels 9 arranged along the first direction X).

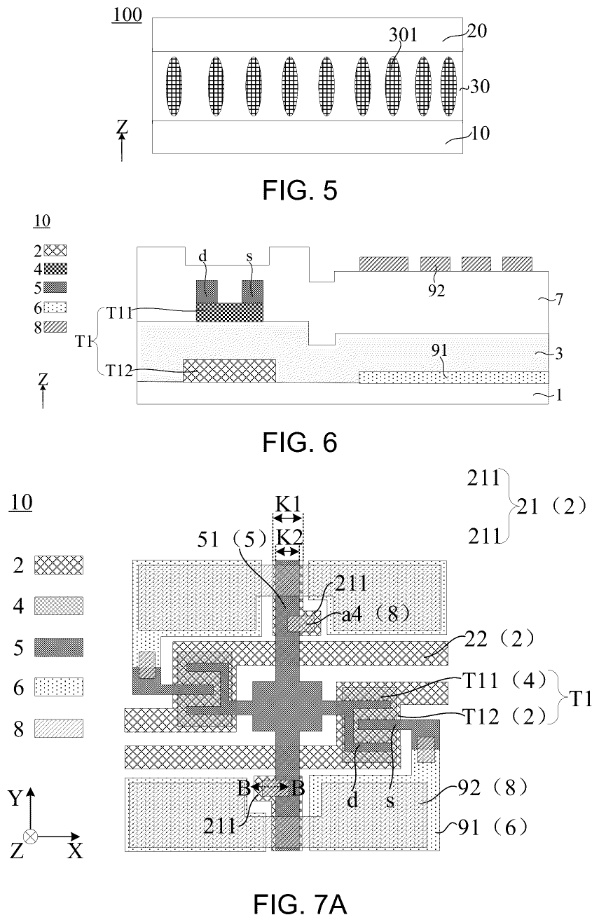

FIG. 5 is a structural diagram of the display panel 100 in accordance with some embodiments. In some embodiments, as shown in FIG. 5, in a case where the display panel 100 is a thin film transistor liquid crystal display (TFT-LCD) panel, the display panel 100 may include an array substrate 10, an opposite substrate 20 and a liquid crystal layer 30. The opposite substrate 20 and the array substrate 10 are disposed opposite to and spaced apart from each other, and the liquid crystal layer 30 is disposed between the array substrate 10 and the opposite substrate 20.

An electric field can be generated in the display panel 100, and liquid crystal molecules 301 in the liquid crystal layer 30 in the display panel 100 may deflect under the action of the electric field. By adjusting the intensity of the electric field applied to the liquid crystal layer 30 in the display panel 100, the degree of deflection of the liquid crystal molecules 301 in the liquid crystal layer 30 may be controlled, thereby controlling the amount of light transmitted through a region where the liquid crystal molecules 301 in the liquid crystal layer 30 are located, enabling the display panel 100 to display images.

For example, with continuous reference to FIG. 5, and in combination with FIG. 3A and FIG. 3B, the electric field for driving the liquid crystal molecules 301 in the liquid crystal layer 30 in the display panel 100 to deflect may be generated when voltages are applied to the pixel electrode 91 and the common electrode 92 in the sub-pixel 9.

For example, with continuous reference to FIG. 5, the opposite substrate 20 in the display panel 100 may be a color filter substrate.

The thin film transistors T1, the pixel electrodes 91 and the common electrodes 92 in the sub-pixels 9 in the display panel 100, as well as the second data lines 51 and the gate lines 22 in the display panel 100 may be disposed in the array substrate 10 in the display panel 100. The array substrate 10 in the display panel 100 will be described in detail below.

FIG. 6 is a cross-sectional view of a local region of the array substrate 10 in accordance with some embodiments. In some embodiments, as shown in FIG. 6, the array substrate 10 includes a substrate 1.

For example, the substrate 1 may be a rigid substrate. For example, the substrate 1 is a glass substrate or a polymethyl methacrylate (PMMA) substrate.

Alternatively, the substrate 1 may be a rigid substrate. For example, the substrate 1 is a polyethylene terephthalate (PET) substrate, a polyethylene naphthalate (PEN) substrate or a polyimide (PI) substrate.

In some embodiments, with continuous reference to FIG. 6, and in combination with FIG. 3A and FIG. 3B, the array substrate 10 further includes a first conductive layer 2. The first conductive layer 2 is located on the substrate 1.

For example, with continuous reference to FIG. 6, and in combination with FIG. 3A and FIG. 3B, the gate patterns T12 of the thin film transistors T1 may be disposed in the first conductive layer 2. That is, the first conductive layer 2 in the array substrate 10 includes the gate patterns T12 of the thin film transistors T1.

For example, with continuous reference to FIG. 3A and FIG. 3B, the gate lines 22 may also be disposed in the first conductive layer 2. That is, the first conductive layer 2 in the array substrate 10 includes the gate lines 22.

For example, the first conductive layer 2 in the array substrate 10 may be obtained by depositing a metal material such as Mo/Ti/Al/Cu (molybdenum/titanium/aluminum/copper) using a physical vapor deposition (PVD) process. For example, the first conductive layer 2 in the array substrate 10 may be obtained by depositing Cu (copper) using PVD process.

In some embodiments, with continuous reference to FIG. 6, the array substrate 10 further includes a first insulating layer 3 and a semiconductor layer 4. The semiconductor layer 4 is located on a side of the first conductive layer 2 away from the substrate 1, and the first insulating layer 3 is located between the semiconductor layer 4 and the first conductive layer 2.

For example, with continuous reference to FIG. 6, and in combination with FIG. 3A and FIG. 3B, the active layer patterns T11 of the thin film transistors T1 may be disposed in the semiconductor layer 4. That is, the semiconductor layer 4 in the array substrate 10 includes the active layer patterns T11 of the thin film transistors T1.

For example, a material of the semiconductor layer 4 may be low temperature polysilicon.

Alternatively, the material of the semiconductor layer 4 may be any one of indium gallium zinc oxide and low temperature polycrystalline oxide. For example, the material of the semiconductor layer 4 is indium gallium zinc oxide (IGZO). As another example, the material of the semiconductor layer 4 is indium gallium zinc tin oxide (IGZTO).

It can be understood that in a case where the material of the semiconductor layer 4 is low temperature polysilicon, the thin film transistor T1 having the active layer pattern T11 located in the semiconductor layer 4 is a low temperature polysilicon thin film transistor.

In case where the material of the semiconductor layer 4 is any one of indium gallium zinc oxide and low temperature polycrystalline oxide, the thin film transistor T1 having the active layer pattern T11 located in the semiconductor layer 4 is an oxide thin film transistor.

For example, the semiconductor layer 4 may be obtained by using an excimer laser annealing process.

Alternatively, the semiconductor layer 4 may be obtained by a physical vapor deposition process.

For example, a material of the first insulating layer 3 may include silicon nitride, silicon oxide or silicon oxynitride, which is obtained by depositing using a plasma enhanced chemical vapor deposition (PECVD) process.

In some embodiments, with continuous reference to FIG. 6, the array substrate 10 further includes a second conductive layer 5. The second conductive layer 5 is located on a side of the first conductive layer 2 away from the substrate 1.

The semiconductor layer 4 in the array substrate 10 may be located between the first conductive layer 2 and the second conductive layer 5. Since the first insulating layer 3 in the array substrate 10 is located between the semiconductor layer 4 and the first conductive layer 2, in a case where the semiconductor layer 4 in the array substrate 10 is located between the first conductive layer 2 and the second conductive layer 5, the first insulating layer 3 in the array substrate 10 is also located between the first conductive layer 2 and the second conductive layer 5.

For example, with continuous reference to FIG. 6, and in combination with FIG. 3A and FIG. 3B, the source contact portion s and the drain contact portion d may be disposed in the second conductive layer 5. That is, the second conductive layer 5 in the array substrate 10 includes the source contact portion s and the drain contact portion d.

With continuous reference to FIG. 6, the active layer pattern T11 of the thin film transistor T1 in the semiconductor layer 4 may be in contact with the source contact portion s and the drain contact portion d in the second conductive layer 5. That is, there is no insulating film layer disposed between the active layer pattern T11 of the thin film transistor T1 in the semiconductor layer 4 and both the source contact portion s and the drain contact portion d in the second conductive layer 5.

For example, with continuous reference to FIG. 3A and FIG. 3B, the second data lines 51 may be disposed in the second conductive layer 5. That is, the second conductive layer 5 in the array substrate 10 includes the second data lines 51.

For example, the second conductive layer 5 in the array substrate 10 may be obtained by depositing a metal material such as Mo/Ti/Al/Cu (molybdenum/titanium/aluminum/copper) using a physical vapor deposition (PVD) process. For example, the second conductive layer 5 in the array substrate 10 may be obtained by depositing Cu (copper) using PVD process.

In some embodiments, with continuous reference to FIG. 6, the array substrate 10 further includes a first electrode layer 6. The first electrode layer 6 is located on a side of the second conductive layer 5 proximate to the substrate 1.

For example, with continuous reference to FIG. 6, the first electrode layer 6 may be located on a side of the first insulating layer 3 proximate to the substrate 1.

For example, in combination with FIG. 3A and FIG. 3B, the pixel electrodes 91 may be disposed in the first electrode layer 6. That is, the first electrode layer 6 in the array substrate 10 includes the pixel electrodes 91.

For example, a material of the first electrode layer 6 in the array substrate 10 may include a transparent conductive material. For example, the material of the first electrode layer 6 in the array substrate 10 includes indium tin oxide (ITO) or indium zinc oxide (IZO).

In some embodiments, with continuous reference to FIG. 6, the array substrate 10 further includes a second electrode layer 8 and a second insulating layer 7. The second insulating layer 7 and the second electrode layer 8 are both located on a side of the second conductive layer 5 in the array substrate 10 away from the substrate 1, and the second electrode layer 8 is located on a side of the second insulating layer 7 away from the substrate 1, that is, the second insulating layer 7 is closer to the substrate 1 than the second electrode layer 8.

For example, with continuous reference to FIG. 6, and in combination with FIG. 3A and FIG. 3B, the common electrodes 92 may be disposed in the second electrode layer 8. That is, the second electrode layer 8 in the array substrate 10 includes the common electrodes 92.

For example, a material of the second electrode layer 8 in the array substrate 10 may include a transparent conductive material. For example, the material of the second electrode layer 8 in the array substrate 10 includes indium tin oxide (ITO) or indium zinc oxide (IZO).

For example, a material of the second insulating layer 7 in the array substrate 10 may include silicon nitride, silicon oxide or silicon oxynitride, which is obtained by depositing using a plasma enhanced chemical vapor deposition (PECVD) process.

For example, with continuous reference to FIG. 6, the first insulating layer 3 and the second insulating layer 7 may be disposed between the first electrode layer 6 and the second electrode layer 8 in the array substrate 10, in which the first insulating layer 3 is closer to the first electrode layer 6 than the second insulating layer 7, and the second insulating layer 7 is closer to the second electrode layer 8 than the first insulating layer 3.

It will be noted that FIG. 3A and FIG. 3B illustrate only the first conductive layer 2, the semiconductor layer 4, the second conductive layer 5, the first electrode layer 6, and the second electrode layer 8 in the array substrate 10, and other film layers in the array substrate 10 are omitted. For example, the substrate 1, the first insulating layer 3 and the second insulating layer 7 in the array substrate 10 are omitted in FIG. 3A and FIG. 3B.

For the sake of clarity in describing the embodiments illustrated by FIG. 3A and FIG. 3B, the semiconductor layer 4, the second conductive layer 5 and the second electrode layer 8 shown in FIG. 3A and FIG. 3B are depicted as transparent to expose other film layers located on a side of the second electrode layer 8 proximate to the substrate 1 (such as the first conductive layer 2, the semiconductor layer 4, the second conductive layer 5, and the first electrode layer 6).

In some embodiments, with continuous reference to FIG. 3A and FIG. 3B, the specific process for charging the sub-pixels 9 in the display panel 100 may be as follows: the gate line 22 controls a thin film transistor T1 in a sub-pixel 9 to be turned on; after the thin film transistor T1 in the sub-pixel 9 is turned on, the second data line 51 charges a pixel electrode 91 in the sub-pixel 9 through the thin film transistor T1 in the sub-pixel 9.

During the charging process of the sub-pixels 9 in the display panel 100, some of the sub-pixels 9 in the display panel 100 may occur insufficient charging, which may easily cause poor display quality of the display panel 100 and affect the display effect of the display panel 100.

For example, with continuous reference to FIG. 3A, in the display panel 100 with the dual gate line structure, the charging time of the sub-pixels 9 in the display panel 100 is generally half the charging time of the sub-pixels 9 in the display panel 100 with the single gate line structure. That is, in the display panel 100 with the dual gate line structure, the charging time of the sub-pixels 9 in the display panel 100 is relatively short, and some of the sub-pixels 9 in the display panel 100 may be insufficiently charged, which may easily cause poor display quality of the display panel 100 and affect the display effect of the display panel 100.

In particular, in a case where the display panel 100 is a display panel with high refresh rate, some of the sub-pixels 9 in the display panel 100 are more likely to occur insufficient charging, which may more easily cause poor display quality of the display panel 100 and affect the display effect of the display panel 100.

In the display panel 100 with the dual gate line structure, the gate driving on the display panel 100 generally follows scanning of a normal “Z” pattern. Therefore, the case where some of the sub-pixels 9 in the display panel 100 are insufficiently charged, will manifest as one column of sub-pixels (i.e., multiple sub-pixels 9 arranged along the second direction Y) being sufficiently charged, while another column of sub-pixels (i.e., multiple sub-pixels 9 arranged along the second direction Y) being insufficiently charged, causing an image shown by the display panel 100 to be prone to stripe defects extending along the second direction Y, thereby affecting the display quality of display panel 100.

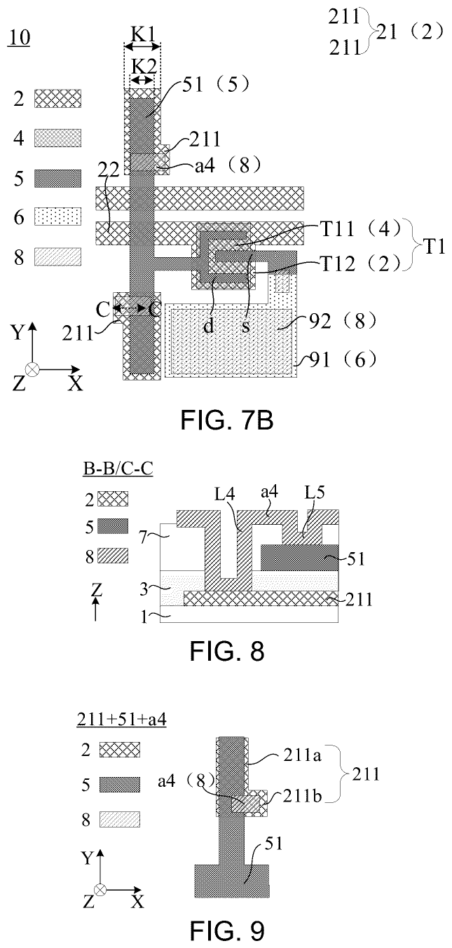

FIG. 7A and FIG. 7B are each a plan view showing a structure of a local region of the array substrate 10 in accordance with some embodiments. In light of this, in some embodiments, as shown in FIG. 7A and FIG. 7B, there is the array substrate 10. It will be noted that the array substrate 10 shown in FIG. 7A is the array substrate 10 in the display panel 100 with the dual gate line structure, while the array substrate 10 shown in FIG. 7B is the array substrate 10 in the display panel 100 with the single gate line structure.

FIG. 7A and FIG. 7B illustrate only the first conductive layer 2, the semiconductor layer 4, the second conductive layer 5, the first electrode layer 6, and the second electrode layer 8 in the array substrate 10, and other film layers in the array substrate 10 are omitted. For example, the substrate 1, the first insulating layer 3 and the second insulating layer 7 in the array substrate 10 are omitted in FIG. 7A and FIG. 7B.

For the sake of clarity in describing the embodiments illustrated by FIG. 7A and FIG. 7B, the semiconductor layer 4, the second conductive layer 5 and the second electrode layer 8 shown in FIG. 7A and FIG. 7B are depicted as transparent to expose other film layers located on a side of the second electrode layer 8 proximate to the substrate 1 (such as the first conductive layer 2, the semiconductor layer 4, the second conductive layer 5, and the first electrode layer 6).

The first conductive layer 2 of the array substrate 10 further includes first data lines 21. The first data line 21 includes a plurality of data sub-lines 211 extending along the second direction Y, and the plurality of data sub-lines 211 are arranged at intervals along the second direction Y.

The second data line 51 in the second conductive layer 5 of the array substrate 10 is connected in parallel to the plurality of data sub-lines 211 included in the first data line 21.

By arranging the first data line 21 in the first conductive layer 2 of the array substrate 10, in which the first data line 21 includes a plurality of data sub-lines 211, and making the second data line 51 in the second conductive layer 5 of the array substrate 10 be connected in parallel to the plurality of data sub-lines 211 included in the first data line 21 in the first conductive layer 2, the overall line resistance of a data line composed of the first data line 21 in the first conductive layer 2 and the second data line 51 in the second conductive layer 5 may be reduced, thereby weakening the resistance-capacitance delay (RC Delay) effect of the data line composed of the first data line 21 in the first conductive layer 2 and the second data line 51 in the second conductive layer 5. When the sub-pixel 9 in the display panel 100 is charged using the data line composed of the first data line 21 in the first conductive layer 2 and the second data line 51 in the second conductive layer 5, it is conducive to improving the charging efficiency of the sub-pixels 9 in the display panel 100, and reducing the probability of insufficient charging of the sub-pixels 9 in the display panel 100, thereby improving the display effect of the display panel 100 including the array substrate 10.

For example, with continuous reference to FIG. 7A and FIG. 7B, one second data line 51 may be connected in parallel to at least one of data sub-lines 211 in one first data line 21.

For example, one second data line 51 may be connected in parallel to one of data sub-lines 211 in one first data line 21, which may reduce the overall line resistance of a data line composed of the first data line 21 in the first conductive layer 2 and the second data line 51 in the second conductive layer 5, thereby weakening the resistance-capacitance delay (RC Delay) effect of the data line composed of the first data line 21 in the first conductive layer 2 and the second data line 51 in the second conductive layer 5. When the sub-pixel 9 in the display panel 100 is charged using the data line composed of the first data line 21 in the first conductive layer 2 and the second data line 51 in the second conductive layer 5, it is conducive to improving the charging efficiency of the sub-pixels 9 in the display panel 100, and reducing the probability of insufficient charging of the sub-pixels 9 in the display panel 100, thereby improving the display effect of the display panel 100 including the array substrate 10.

As another example, with continuous reference to FIG. 7A and FIG. 7B, one second data line 51 may be connected in parallel to multiple ones of data sub-lines 211 in one first data line 21, which may further reduce the overall line resistance of a data line composed of the first data line 21 in the first conductive layer 2 and the second data line 51 in the second conductive layer 5, thereby further weakening the resistance-capacitance delay (RC Delay) effect of the data line composed of the first data line 21 in the first conductive layer 2 and the second data line 51 in the second conductive layer 5. When the sub-pixel 9 in the display panel 100 is charged using the data line composed of the first data line 21 in the first conductive layer 2 and the second data line 51 in the second conductive layer 5, it is conducive to further improving the charging efficiency of the sub-pixels 9 in the display panel 100, and further reducing the probability of insufficient charging of the sub-pixels 9 in the display panel 100, thereby further improving the display effect of the display panel 100 including the array substrate 10.

For example, with continuous reference to FIG. 7A and FIG. 7B, in a case where the first conductive layer 2 of the array substrate 10 includes the first data line 21 and the gate line 22, that is, the first data line 21 and the gate line 22 are arranged in the same layer, since the plurality of data sub-lines 211 included in the first data line 21 extend along the second direction Y and arranged at intervals along the second direction Y, and the gate line 22 extends along the first direction X, where the first direction X and the second direction Y intersect, the gate line 22 passes between two adjacent data sub-lines 211 and is spaced apart from the two adjacent data sub-lines 211, in order to avoid the intersection of the plurality of data sub-lines 211 included in the first data line 21 and the gate line 22 in the first conductive layer 2.

It will be noted that the “same layer” refers to a layer structure formed by forming a film layer for forming a specific pattern through a same film forming process and then performing a single patterning process using a same mask. According to different specific patterns, the single patterning process may include several exposure, development or etching processes. These specific patterns (i.e., the first data lines 21 and the gate lines 22) may also be at different heights or have different thicknesses.

With continuous reference to FIG. 7A and FIG. 7B, in the first conductive layer 2 of the array substrate 10, in a case where the gate line 22 passes between two adjacent data sub-lines 211 and is spaced apart from the two adjacent data sub-lines 211, the two adjacent data sub-lines 211 in the second direction Y are provided therebetween with at least one gate line 22.

For example, with continuous reference to FIG. 7A, in a case where the array substrate 10 is an array substrate 10 in the display panel 100 with the dual gate line structure, in the first conductive layer 2 of the array substrate 10, two adjacent data sub-lines 211 in the second direction Y may be provided therebetween with two gate lines 22.

As another example, with continuous reference to FIG. 7B, in a case where the array substrate 10 is an array substrate 10 in the display panel 100 with the single gate line structure, in the first conductive layer 2 of the array substrate 10, two adjacent data sub-lines 211 in the second direction Y may be provided therebetween with one gate line 22.

For example, with continuous reference to FIG. 7A and FIG. 7B, a dimension K1, along the first direction X, of the data sub-line 211 included in the first data line 21 in the first conductive layer 2 may be greater than a dimension K2, along the first direction X, of the second data line 51 in the second conductive layer 5. That is, the dimension K1, along the first direction X, of the data sub-line 211 included in the first data line 21 in the first conductive layer 2 is relatively large, which may further reduce the overall line resistance of a data line composed of the first data line 21 in the first conductive layer 2 and the second data line 51 in the second conductive layer 5, thereby further weakening the resistance-capacitance delay (RC Delay) effect of the data line composed of the first data line 21 in the first conductive layer 2 and the second data line 51 in the second conductive layer 5. When the sub-pixel 9 in the display panel 100 is charged using the data line composed of the first data line 21 in the first conductive layer 2 and the second data line 51 in the second conductive layer 5, it is conducive to further improving the charging efficiency of the sub-pixels 9 in the display panel 100, and further reducing the probability of insufficient charging of the sub-pixels 9 in the display panel 100, thereby further improving the display effect of the display panel 100 including the array substrate 10.

For example, with continuous reference to FIG. 7A and FIG. 7B, onto the substrate 1, orthographic projections of the plurality of data sub-lines 211 included in the first data line 21 in the first conductive layer 2 at least partially overlap with an orthographic projection of the second data line 51 in the second conductive layer 5.

It will be noted that FIG. 7A and FIG. 7B only take an example where onto the substrate 1, orthographic projections of the plurality of data sub-lines 211 included in the first data line 21 in the first conductive layer 2 partially overlap with an orthographic projection of the second data line 51 in the second conductive layer 5, to schematically illustrate some embodiments of the present disclosure. However, the relative position relationship between the plurality of data sub-lines 211 included in the first data line 21 in the first conductive layer 2 and the second data line 51 in the second conductive layer 5 in the present disclosure includes but is not limited to the above. For example, onto the substrate 1, orthographic projections of the plurality of data sub-lines 211 included in the first data line 21 in the first conductive layer 2 may be located within a range of an orthographic projection of the second data line 51 in the second conductive layer 5.

The materials of the plurality of data sub-lines 211 included in the first data line 21 in the first conductive layer 2 and the second data line 51 in the second conductive layer 5 generally include a non-transparent metal (such as copper). By making the orthographic projections of the plurality of data sub-lines 211 included in the first data line 21 in the first conductive layer 2 onto the substrate 1 at least partially overlap with the orthographic projection of the second data line 51 in the second conductive layer 5 onto the substrate 1, the total area of an overall structure formed by the orthographic projections of the plurality of data sub-lines 211 included in the first data line 21 in the first conductive layer 2 and the second data line 51 in the second conductive layer 5 onto the substrate 1 may be reduced, which is conducive to reducing an area ratio of the overall structure formed by the orthographic projections of the plurality of data sub-lines 211 included in the first data line 21 in the first conductive layer 2 and the second data line 51 in the second conductive layer 5 onto the substrate 1, i.e., conducive to reducing an area ratio of an orthographic projection of the non-transparent metal onto the substrate 1, thereby contributing to an increase in the aperture ratio of the array substrate 10, to improve the display effect of the display panel 100 including the array substrate 10.

The connection method between the second data line 51 in the second conductive layer 5 of the array substrate 10 and the plurality of data sub-lines 211 included in the first data line 21 in the first conductive layer 2 will be described in detail below.

FIG. 8 is a cross-sectional view of the array substrate 10 shown in FIG. 7A taken along the section line B-B or the array substrate 10 shown in FIG. 7B taken along the section line C-C. In some embodiments, as shown in FIG. 8, and in combination with FIG. 7A and FIG. 7B, the second electrode layer 8 of the array substrate 10 further includes fourth transfer patterns a4.

The array substrate 10 further includes fourth connection portions L4 and fifth connection portions L5. The data sub-line 211 included in the first data line 21 in the first conductive layer 2 is connected to a fourth transfer pattern a4 in the second electrode layer 8 through a fourth connection portion L4, and the second data line 51 in the second conductive layer 5 is connected to the fourth transfer pattern a4 in the second electrode layer 8 through a fifth connection portion L5. That is, the data sub-line 211 included in the first data line 21 in the first conductive layer 2 and the second data line 51 in the second conductive layer 5 are both connected to the fourth transfer pattern a4 in the second electrode layer 8, to enable the data sub-line 211 included in the first data line 21 in the first conductive layer 2 and the second data line 51 in the second conductive layer 5 to be connected in parallel.

FIG. 9 is a plan view showing structures of the data sub-line 211 in the first conductive layer 2, the second data line 51 in the second conductive layer 5, and the fourth transfer pattern a4 in the second electrode layer 8 in accordance with some embodiments. For example, as shown in FIG. 9, in a case where the data sub-line 211 included in the first data line 21 in the first conductive layer 2 is connected to the fourth transfer pattern a4 in the second electrode layer 8 through the fourth connection portion L4, and the second data line 51 in the second conductive layer 5 is connected to the fourth transfer pattern a4 in the second electrode layer 8 through the fifth connection portion L5, the data sub-line 211 in the first conductive layer 2 may include a main body portion 211a extending along the second direction Y, and a protruding portion 211b connected to the main body portion 211a.

Onto the substrate 1, an orthographic projection of at least a partial region of the protruding portion 211b of the data sub-line 211 in the first conductive layer 2 is non-overlapping with an orthographic projection of the second data line 51 in the second conductive layer 5. Here, “the data sub-line 211 included in the first data line 21 in the first conductive layer 2 being connected to the fourth transfer pattern a4 in the second electrode layer 8 through the fourth connection portion L4” described above may specifically mean that the protruding portion 211b of the data sub-line 211 included in the first data line 21 in the first conductive layer 2 is connected to the fourth transfer pattern a4 in the second electrode layer 8 through the fourth connection portion L4.

Onto the substrate 1, an orthographic projection of the main body portion 211a of the data sub-line 211 in the first conductive layer 2 may at least partially overlap with an orthographic projection of the second data line 51 in the second conductive layer 5.

By making the orthographic projection of the main body portion 211a of the data sub-line 211 in the first conductive layer 2 onto the substrate 1 at least partially overlap with the orthographic projection of the second data line 51 in the second conductive layer 5 onto the substrate 1, the total area of an overall structure formed by the orthographic projections of the main body portion 211a of the data sub-line 211 in the first conductive layer 2 and the second data line 51 in the second conductive layer 5 onto the substrate 1 may be reduced, which is conducive to reducing an area ratio of the overall structure formed by the orthographic projections of the main body portion 211a of the data sub-line 211 in the first conductive layer 2 and the second data line 51 in the second conductive layer 5 onto the substrate 1.

In a case where the materials of the main body portion 211a of the data sub-line 211 in the first conductive layer 2 and the second data line 51 in the second conductive layer 5 include a non-transparent metal (such as copper), by reducing the area ratio of the overall structure formed by the orthographic projections of the main body portion 211a of the data sub-line 211 in the first conductive layer 2 and the second data line 51 in the second conductive layer 5 onto the substrate 1, an area ratio of an orthographic projection of the non-transparent metal onto the substrate 1 may be reduced, thereby contributing to an increase in the aperture ratio of the array substrate 10, to improve the display effect of the display panel 100 including the array substrate 10.

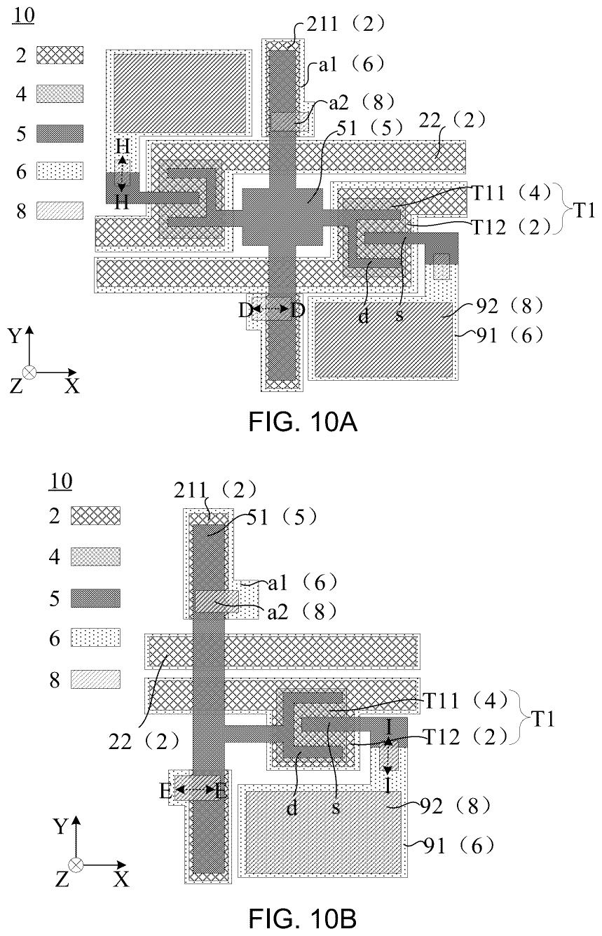

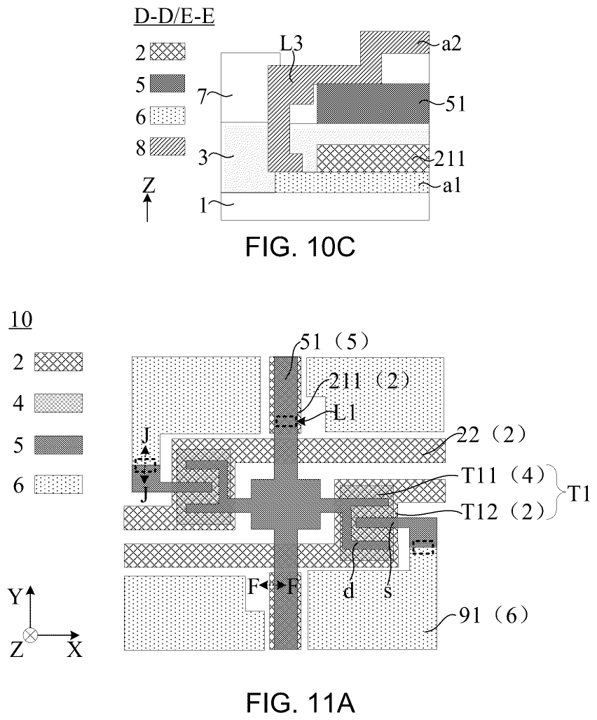

In some embodiments, as shown in FIG. 10A, FIG. 10B and FIG. 10C, in which FIG. 10A and FIG. 10B are each a plan view showing a structure of a local region of the array substrate 10 in accordance with some embodiments, and FIG. 10C is a cross-sectional view of the array substrate 10 shown in FIG. 10A taken along the section line D-D or the array substrate 10 shown in FIG. 10B taken along the section line E-E. It will be noted that the array substrate 10 shown in FIG. 10A is an array substrate 10 in the display panel 100 with the dual gate line structure, and the array substrate 10 shown in FIG. 10B is an array substrate 10 in the display panel 100 with the single gate line structure.

FIG. 10A and FIG. 10B illustrate only the first conductive layer 2, the semiconductor layer 4, the second conductive layer 5, the first electrode layer 6, and the second electrode layer 8 in the array substrate 10, and other film layers in the array substrate 10 are omitted. For example, the substrate 1, the first insulating layer 3 and the second insulating layer 7 in the array substrate 10 are omitted in FIG. 10A and FIG. 10B.

For the sake of clarity in describing the embodiments illustrated by FIG. 10A and FIG. 10B, the semiconductor layer 4, the second conductive layer 5 and the second electrode layer 8 shown in FIG. 10A and FIG. 10B are depicted as transparent to expose other film layers located on a side of the second electrode layer 8 proximate to the substrate 1 (such as the first conductive layer 2, the semiconductor layer 4, the second conductive layer 5, and the first electrode layer 6).

The array substrate 10 further includes third connection portions L3. The first electrode layer 6 of the array substrate 10 further includes first transfer patterns a1, and the second electrode layer 8 further includes second transfer patterns a2.

A first transfer pattern a1 in the first electrode layer 6 is connected to the data sub-line 211 in the first conductive layer 2, and a second transfer pattern a2 in the second electrode layer 8, the second data line 51 in the second conductive layer 5 and the first transfer pattern a1 in the first electrode layer 6 are all connected to the third connection portion L3, that is, the data sub-line 211 in the first conductive layer 2 and the second data line 51 in the second conductive layer 5 are both connected to the first transfer pattern a1 in the first electrode layer 6, to enable the data sub-line 211 included in the first data line 21 in the first conductive layer 2 and the second data line 51 in the second conductive layer 5 to be connected in parallel.

Since the data sub-line 211 in the first conductive layer 2 is connected to the first transfer pattern a1 in the first electrode layer 6, and the second data line 51 in the second conductive layer 5, the second transfer pattern a2 in the second electrode layer 8 and the first transfer pattern a1 in the first electrode layer 6 are all connected to the third connection portion L3, for the data sub-line 211 in the first conductive layer 2 and the second data line 51 in the second conductive layer 5, only the second data line 51 in the second conductive layer 5 is connected to the second transfer pattern a2 in the second electrode layer 8, and the data sub-line 211 in the first conductive layer 2 is not connected to the second transfer pattern a2 in the second electrode layer 8. Since the second conductive layer 5 is located between the first conductive layer 2 and the second electrode layer 8, in a case where the data sub-line 211 in the first conductive layer 2 is not connected to the second transfer pattern a2 in the second electrode layer 8, the data sub-line 211 in the first conductive layer 2 do not require to be provided with such a partial region, whose orthographic projection onto the substrate 1 is non-overlapping with the orthographic projection of the second data line 51 in the second conductive layer 5 onto the substrate 1, for enabling the data sub-line 211 in the first conductive layer 2 to be connected to the second transfer pattern a2 in the second electrode layer 8. This arrangement is conducive to increasing the overlapping area of the orthographic projections of the data sub-line 211 in the first conductive layer 2 and the second data line 51 in the second conductive layer 5 onto the substrate 1, and further reducing the total area of an overall structure formed by the orthographic projections of the data sub-line 211 in the first conductive layer 2 and the second data line 51 in the second conductive layer 5 onto the substrate 1, which is conducive to further reducing an area ratio of the orthographic projections of the data sub-line 211 in the first conductive layer 2 and the second data line 51 in the second conductive layer 5 onto the substrate 1.

In a case where the materials of the data sub-line 211 in the first conductive layer 2 and the second data line 51 in the second conductive layer 5 include a non-transparent metal (such as copper), by further reducing the area ratio of the overall structure formed by the orthographic projections of the data sub-line 211 in the first conductive layer 2 and the second data line 51 in the second conductive layer 5 onto the substrate 1, the area ratio of the orthographic projection of the non-transparent metal onto the substrate 1 may be further reduced, thereby contributing to an increase in the aperture ratio of the array substrate 10, to further improve the display effect of the display panel 100 including the array substrate 10.

For example, with continuous reference to FIG. 10C, and in combination with FIG. 10A and FIG. 10B, the first transfer pattern a1 in the first electrode layer 6 may overlap and contact the data sub-line 211 in the first conductive layer 2. That is, there is no insulating film layer between the first transfer pattern a1 in the first electrode layer 6 and the data sub-line 211 in the first conductive layer 2, and the orthographic projections of the first transfer pattern a1 in the first electrode layer 6 and the data sub-line 211 in the first conductive layer 2 onto the substrate 1 overlap.

For example, with continuous reference to FIG. 10C, the third connection portion L3 in the array substrate 10 may penetrate the first insulating layer 3 and the second insulating layer 7 in the array substrate 10.

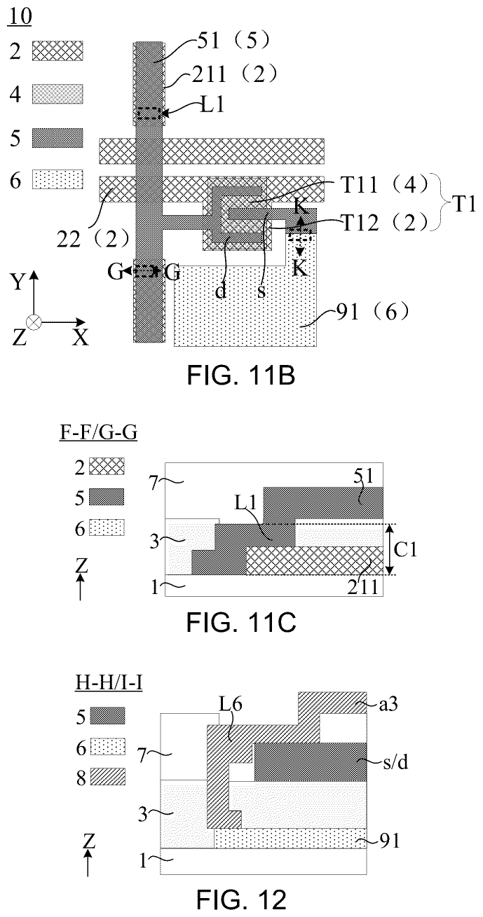

In some embodiments, as shown in FIG. 11A, FIG. 11B and FIG. 11C, in which FIG. 11A and FIG. 11B are each a plan view showing a structure of a local region of the array substrate 10 in accordance with some embodiments, and FIG. 11C is a cross-sectional view of the array substrate 10 shown in FIG. 11A taken along the section line F-F or the array substrate 10 shown in FIG. 11B taken along the section line G-G. It will be noted that the array substrate 10 shown in FIG. 11A is an array substrate 10 in the display panel 100 with the dual gate line structure, and the array substrate 10 shown in FIG. 11B is an array substrate 10 in the display panel 100 with the single gate line structure.

FIG. 11A and FIG. 11B illustrate only the first conductive layer 2, the semiconductor layer 4, the second conductive layer 5, and the first electrode layer 6 in the array substrate 10, and other film layers in the array substrate 10 are omitted. For example, the substrate 1, the first insulating layer 3, the second insulating layer 7, and the second electrode layer 8 in the array substrate 10 are omitted in FIG. 11A and FIG. 11B.

For the sake of clarity in describing the embodiments illustrated by FIG. 11A and FIG. 11B, the semiconductor layer 4 and the second conductive layer 5 shown in FIG. 11A and FIG. 11B are depicted as transparent to expose other film layers located on a side of the second conductive layer 5 proximate to the substrate 1 (such as the first conductive layer 2, the semiconductor layer 4, the second conductive layer 5, and the first electrode layer 6).

The array substrate 10 further includes first connection portions L1. A first connection portion L1 penetrates the first insulating layer 3 in the array substrate 10, and two ends of the first connection portion L1 are connected to the data sub-line 211 in the first conductive layer 2 and the second data line 51 in the second conductive layer 5, respectively. That is, the data sub-line 211 in the first conductive layer 2 and the second data line 51 in the second conductive layer 5 are connected through the first connection portion L 1.

By providing the first connection portion L1 in the array substrate 10, and making the data sub-line 211 in the first conductive layer 2 and the second data line 51 in the second conductive layer 5 be connected through the first connection portion L1, the following effect may be obtained. In an aspect, since the first connection portion L1 only penetrates the first insulating layer 3 in the array substrate 10, the first connection portion L1 has a relatively small length C1, and thus the first connection portion L1 has a relatively small resistance. In a case where the data sub-line 211 in the first conductive layer 2 and the second data line 51 in the second conductive layer 5 are connected through the first connection portion L1, the line resistance of the first data line 21 in the first conductive layer 2, the second data line 51 in the second conductive layer 5 and the first connection portion L1 as a whole may be reduced, thereby weakening the resistance-capacitance delay (RC Delay) effect of the first data line 21 in the first conductive layer 2, the second data line 51 in the second conductive layer 5 and the first connection portion L1 as a whole. In the case where the data sub-line 211 in the first conductive layer 2 and the second data line 51 in the second conductive layer 5 are connected through the first connection portion L1, when the sub-pixel 9 in the display panel 100 is charged using the data line composed of the first data line 21 in the first conductive layer 2 and the second data line 51 in the second conductive layer 5, it is conducive to improving the charging efficiency of the sub-pixels 9 in the display panel 100, and reducing the probability of insufficient charging of the sub-pixels 9 in the display panel 100, thereby improving the display effect of the display panel 100 including the array substrate 10.

It will be noted that the above “length of the first connection portion L1” refers to a dimension of the first connection portion L1 along the third direction Z (i.e., a direction perpendicular to the substrate 1). The following description about “the length of the first connection portion L1” also follows this description and will not be repeated.

In another aspect, since the data sub-line 211 in the first conductive layer 2 and the second data line 51 in the second conductive layer 5 are directly connected through the first connection portion L1, that is, the data sub-line 211 in the first conductive layer 2 and the second data line 51 in the second conductive layer 5 do not need to be connected through a transfer pattern, the data sub-line 211 in the first conductive layer 2 do not require to be provided with such a partial region, whose orthographic projection onto the substrate 1 is non-overlapping with the orthographic projection of the second data line 51 in the second conductive layer 5 onto the substrate 1, for enabling the data sub-line 211 in the first conductive layer 2 to be connected to the transfer pattern, which is conducive to increasing the overlapping area of the orthographic projections of the data sub-line 211 in the first conductive layer 2 and the second data line 51 in the second conductive layer 5 onto the substrate 1, and further reducing the total area of an overall structure formed by the orthographic projections of the data sub-line 211 in the first conductive layer 2 and the second data line 51 in the second conductive layer 5 onto the substrate 1, which is conducive to further reducing an area ratio of the orthographic projections of the data sub-line 211 in the first conductive layer 2 and the second data line 51 in the second conductive layer 5 onto the substrate 1.

In a case where the materials of the data sub-line 211 in the first conductive layer 2 and the second data line 51 in the second conductive layer 5 include a non-transparent metal (such as copper), by further reducing the area ratio of the overall structure formed by the orthographic projections of the data sub-line 211 in the first conductive layer 2 and the second data line 51 in the second conductive layer 5 onto the substrate 1, the area ratio of the orthographic projection of the non-transparent metal onto the substrate 1 may be further reduced, thereby contributing to an increase in the aperture ratio of the array substrate 10, to further improve the display effect of the display panel 100 including the array substrate 10.

For example, with continuous reference to FIG. 11A and FIG. 11B, onto the substrate 1, an orthographic projection of the first connection portion L1 is located within a range of at least one of orthographic projections of the data sub-line 211 in the first conductive layer 2 and the second data line 51 in the second conductive layer 5.

For example, with continuous reference to FIG. 11A and FIG. 11B, onto the substrate 1, the orthographic projection of the first connection portion L1 is located within both the range of the orthographic projection of the data sub-line 211 in the first conductive layer 2 and the range of the orthographic projection of the second data line 51 in the second conductive layer 5.

As another example, onto the substrate 1, the orthographic projection of the first connection portion L1 is located within the range of the orthographic projection of the data sub-line 211 in the first conductive layer 2.

As another example, the orthographic projection of the first connection portion L1 is located within the range of the orthographic projection of the second data line 51 in the second conductive layer 5.

The connection between the pixel electrode 91 in the first electrode layer 6 of the array substrate 10 and the source contact portion s or the drain contact portion d in the second conductive layer 5 will be described in detail below.

FIG. 12 is a cross-sectional view of the array substrate 10 shown in FIG. 10A taken along the section line H-H or the array substrate 10 shown in FIG. 10B taken along the section line I-I. In some embodiments, as shown in FIG. 12, the second electrode layer 8 of the array substrate 10 further includes third transfer patterns a3. The source contact portion s or the drain contact portion d in the second conductive layer 5 of the array substrate 10 may be connected to the pixel electrode 91 in the first electrode layer 6 through a third transfer pattern a3 in the second electrode layer 8.

For example, with continuous reference to FIG. 12, the array substrate 10 further includes sixth connection portions L6. The sixth connection portions L6 penetrate the first insulating layer 3 and the second insulating layer 7 of the array substrate 10. The source contact portion s or the drain contact portion d in the second conductive layer 5 of the array substrate 10, the third transfer pattern a3 in the second electrode layer 8, and the pixel electrode 91 in the first electrode layer 6 may be connected through a sixth connection portion L6.

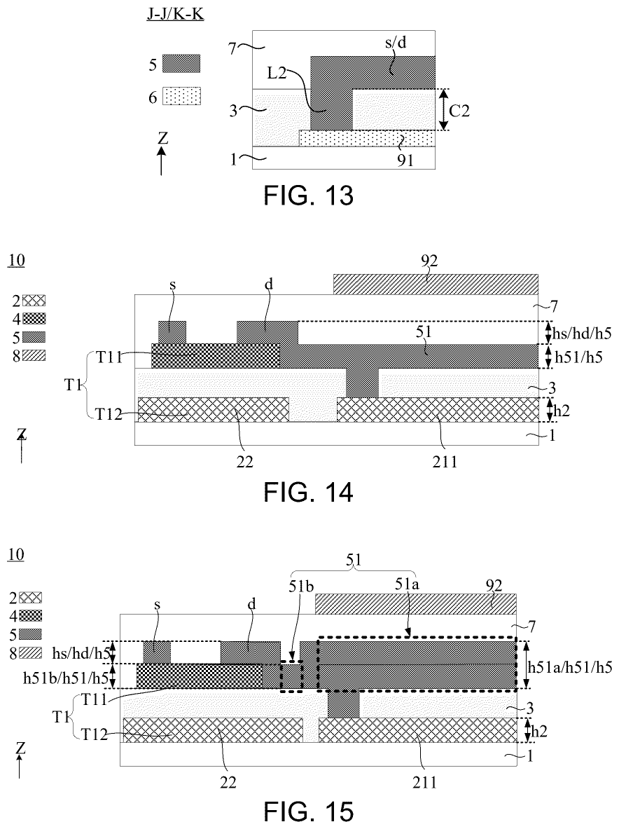

FIG. 13 is a cross-sectional view of the array substrate 10 shown in FIG. 11A taken along the section line J-J or the array substrate 10 shown in FIG. 11B taken along the section line K-K. In some embodiments, as shown in FIG. 13, the array substrate 10 further includes second connection portions L2. The second connection portions L2 penetrate the first insulating layer 3 in the array substrate 10. One end of a second connection portion L2 is connected to the source contact portion s or the drain contact portion d in the second conductive layer 5, and the other end of the second connection portion L2 is connected to the pixel electrode 91 in the first electrode layer 6. That is, the source contact portion s or the drain contact portion d in the second conductive layer 5 may be connected to the pixel electrode 91 in the first electrode layer 6 through the second connection portion L2.

By providing a second connection portion L2 in the array substrate 10, and making the source contact portion s or the drain contact portion d in the second conductive layer 5 to be connected to the pixel electrode 91 in the first electrode layer 6 through the second connection portion L2, since the second connection portion L2 only penetrates the first insulating layer 3 of the array substrate 10, the second connection portion L2 has a relatively small length C2, and thus the second connection portion L2 has a relatively small the resistance. In a case where the source contact portion s or the drain contact portion d in the second conductive layer 5 is connected to the pixel electrode 91 in the first electrode layer 6 through the second connection portion L2, when the thin film transistor T1 in the sub-pixel 9 is turned on, enabling the sub-pixel 9 in the display panel 100 to be charged, it is conducive to improving the charging efficiency of the sub-pixels 9 in the display panel 100, and reducing the probability of insufficient charging of the sub-pixels 9 in the display panel 100, thereby improving the display effect of the display panel 100 including the array substrate 10.

It will be noted that the above “length of the second connection portion L2” refers to a dimension of the second connection portion L2 along the third direction Z (i.e., a direction perpendicular to the substrate 1). The following description about “the length of the second connection portion L2” also follows this description and will not be repeated.

The following describes in detail the setting for the thickness hs of the source contact portion s, the thickness hd of the drain contact portion d and the thickness h51 of the second data line 51 in the second conductive layer 5 of the array substrate 10, as well as the thickness h2 of the first conductive layer 2 of the array substrate 10.

FIG. 14 and FIG. 15 are each a cross-sectional view of a local region of the array substrate 10 in accordance with some embodiments. In some embodiments, as shown in FIG. 14 and FIG. 15, the thickness hs of the source contact portion s in the second conductive layer 5 of the array substrate 10 may range from 3,000 angstroms to 8,000 angstroms.

It will be noted that the above “thickness of the source contact portion s” refers to a dimension of the source contact portion s along the third direction Z (i.e., the direction perpendicular to the substrate 1). The following description of “the thickness of the source contact portion s” also follows this description and will not be repeated.

For example, the thickness hs of the source contact portion s in the second conductive layer 5 of the array substrate 10 (i.e., the dimension of the source contact portion s along the third direction Z) may be 3,000 angstroms, 3,500 angstroms, 4,000 angstroms, 4,500 angstroms, 5,000 angstroms, 5,500 angstroms, 6,000 angstroms, 6,500 angstroms, 7,000 angstroms, 7,500 angstroms, or 8,000 angstroms.

With continuous reference to FIG. 14 and FIG. 15, the thickness hd of the drain contact portion d in the second conductive layer 5 of the array substrate 10 may range from 3,000 angstroms to 8,000 angstroms.

It will be noted that the above “thickness of the drain contact portion d” refers to a dimension of the drain contact portion d along the third direction Z (i.e., the direction perpendicular to the substrate 1). The following description of “the thickness of the drain contact portion d” also follows this description and will not be repeated.

For example, the thickness hd of the drain contact portion d in the second conductive layer 5 of the array substrate 10 (i.e., the dimension of the drain contact portion d along the third direction Z) may be 3,000 angstroms, 3,500 angstroms, 4,000 angstroms, 4,500 angstroms, 5,000 angstroms, 5,500 angstroms, 6,000 angstroms, 6,500 angstroms, 7,000 angstroms, 7,500 angstroms, or 8,000 angstroms.

With continuous reference to FIG. 14 and FIG. 15, the thickness h2 of the first conductive layer 2 of the array substrate 10 may range from 3,000 angstroms to 10,000 angstroms.

It will be noted that the above “thickness of the first conductive layer 2” refers to a dimension of the first conductive layer 2 along the third direction Z (i.e., the direction perpendicular to the substrate 1). The following description about “the thickness of the first conductive layer 2” also follows this description and will not be repeated.

For example, the thickness h2 of the first conductive layer 2 of the array substrate 10 (i.e., the dimension of the first conductive layer 2 along the third direction Z) may be 3,000 angstroms, 3,500 angstroms, 4,000 angstroms, 4,500 angstroms, 5,000 angstroms, 5,500 angstroms, 6,000 angstroms, 6,500 angstroms, 7,000 angstroms, 7,500 angstroms, 8,000 angstroms, 8,500 angstroms, 9,000 angstroms, 9,500 angstroms, or 10,000 angstroms.

In some embodiments, with continuous reference to FIG. 14 and FIG. 15, the thickness hs of the source contact portion s (i.e., the dimension of the source contact portion s along the third direction Z) and the thickness hd of the drain contact portion d (i.e., the dimension of the drain contact portion d along the third direction Z) in the second conductive layer 5 of the array substrate 10 are both less than the thickness h2 of the first conductive layer 2 of the array substrate 10 (i.e., the dimension of the first conductive layer 2 along the third direction Z). That is, the thickness hs of the source contact portion s and the thickness hd of the drain contact portion d in the second conductive layer 5 of the array substrate 10 are relatively small, and the thickness h2 of the first conductive layer 2 of the array substrate 10 is relatively large.

With continuous reference to FIG. 14 and FIG. 15, in a case where the active layer pattern T11 of the thin film transistor T1 in the semiconductor layer 4 of the array substrate 10 is in contact with the source contact portion s and the drain contact portion d in the second conductive layer 5, by making the thickness hs of the source contact portion s (i.e., the dimension of the source contact portion s along the third direction Z) and the thickness hd of the drain contact portion d (i.e., the dimension of the drain contact portion d along the third direction Z) in the second conductive layer 5 of the array substrate 10 both less than the thickness h2 of the first conductive layer 2 of the array substrate 10 (i.e., the dimension of the first conductive layer 2 along the third direction Z), i.e., making the thickness hs of the source contact portion s (i.e., the dimension of the source contact portion s along the third direction Z) and the thickness hd of the drain contact portion d (i.e., the dimension of the drain contact portion d along the third direction Z) in the second conductive layer 5 of the array substrate 10 be relatively small, when the source contact portion s and the drain contact portion d in the second conductive layer 5 are formed by an etching process, the etching time is relatively short, which may reduce or avoid etching on the channel region of the active layer pattern T11 of the thin film transistor T1 in the semiconductor layer 4 during the etching process, thereby reducing the channel length of the active layer pattern T11 of the thin film transistor T1.

It can be understood that the channel length of the active layer pattern T11 of the thin film transistor T1 is negatively correlated with an on-state current lon of the thin film transistor T1, that is, the on-state current lon of the thin film transistor T1 increases as the channel length of the active layer pattern T11 of the thin film transistor T1 decreases. Therefore, the channel length of the active layer pattern T11 of the thin film transistor T1 in the sub-pixel 9 is reduced, which may increase the on-state current lon of the thin film transistor T1. When the thin film transistor T1 in the sub-pixel 9 is turned on to charge the sub-pixel 9 in the display panel 100, it is conducive to improving the charging efficiency of the sub-pixels 9 in the display panel 100 and reducing the probability of insufficient charging of the sub-pixels 9 in the display panel 100, thereby improving the display effect of the display panel 100 including the array substrate 10.

For example, with continuous reference to FIG. 14 and FIG. 15, in a case where the thickness hs of the source contact portion s (i.e., the dimension of the source contact portion s along the third direction Z) and the thickness hd of the drain contact portion d (i.e., the dimension of the drain contact portion d along the third direction Z) in the second conductive layer 5 of the array substrate 10 are both less than the thickness h2 of the first conductive layer 2 of the array substrate 10 (i.e., the dimension of the first conductive layer 2 along the third direction Z), the thickness hs of the source contact portion s in the second conductive layer 5 of the array substrate 10 (i.e., the dimension of the source contact portion s along the third direction Z) may range from 3,000 angstroms to 6,000 angstroms.

For example, the thickness hs of the source contact portion s in the second conductive layer 5 of the array substrate 10 (i.e., the dimension of the source contact portion s along the third direction Z) may be 3,000 angstroms, 3,500 angstroms, 4,000 angstroms, 4,500 angstroms, 5,000 angstroms, 5,500 angstroms, or 6,000 angstroms.

For example, with continuous reference to FIG. 14 and FIG. 15, in a case where the thickness hs of the source contact portion s (i.e., the dimension of the source contact portion s along the third direction Z) and the thickness hd of the drain contact portion d (i.e., the dimension of the drain contact portion d along the third direction Z) in the second conductive layer 5 of the array substrate 10 are both less than the thickness h2 of the first conductive layer 2 of the array substrate 10 (i.e., the dimension of the first conductive layer 2 along the third direction Z), the thickness hd of the drain contact portion d in the second conductive layer 5 of the array substrate 10 (i.e., the dimension of the drain contact portion d along the third direction Z) may range from 3,000 angstroms to 6,000 angstroms.

For example, the thickness hd of the drain contact portion d in the second conductive layer 5 of the array substrate 10 (i.e., the dimension of the drain contact portion d along the third direction Z) may be 3,000 angstroms, 3,500 angstroms, 4,000 angstroms, 4,500 angstroms, 5,000 angstroms, 5,500 angstroms, or 6,000 angstroms.

For example, with continuous reference to FIG. 14 and FIG. 15, in a case where the thickness hs of the source contact portion s (i.e., the dimension of the source contact portion s along the third direction Z) and the thickness hd of the drain contact portion d (i.e., the dimension of the drain contact portion d along the third direction Z) in the second conductive layer 5 of the array substrate 10 are both less than the thickness h2 of the first conductive layer 2 of the array substrate 10 (i.e., the dimension of the first conductive layer 2 along the third direction Z), the thickness h2 of the first conductive layer 2 of the array substrate 10 (i.e., the dimension of the first conductive layer 2 along the third direction Z) may range from 6,000 angstroms to 10,000 angstroms.

For example, the thickness h2 of the first conductive layer 2 of the array substrate 10 (i.e., the dimension of the first conductive layer 2 along the third direction Z) may be 6,000 angstroms, 6,500 angstroms, 7,000 angstroms, 7,500 angstroms, 8,000 angstroms, 8,500 angstroms, 9,000 angstroms, 9,500 angstroms, or 10,000 angstroms.

With continuous reference to FIG. 14 and FIG. 15, the thickness h5 of the second conductive layer 5 of the array substrate 10 may be set uniformly, or the thickness h5 of the second conductive layer 5 of the array substrate 10 may be set non-uniformly.

It will be noted that the above “thickness of the second conductive layer 5” refers to a dimension of the second conductive layer 5 along the third direction Z (i.e., the direction perpendicular to the substrate 1). The following description about “the thickness of the second conductive layer 5” also follows this description and will not be repeated.

The following is a detailed description of embodiments in which the thickness h5 of the second conductive layer 5 of the array substrate 10 (i.e., the dimension of the second conductive layer 5 along the third direction Z) is set uniformly.

In some embodiments, with continuous reference to FIG. 14, the thickness h51 of the second data line 51 in the second conductive layer 5 of the array substrate 10 and the thickness hs of the source contact portion s in the second conductive layer 5 (i.e., the dimension of the source contact portion s along the third direction Z) are equal.

It will be noted that the above “thickness of the second data line 51” refers to a dimension of the second data line 51 along the third direction Z (i.e., the direction perpendicular to the substrate 1). The following description about “the thickness of the second data line 51” also follows this description and will not be repeated.

Since the second data line 51 and the source contact portion s are both located in the second conductive layer 5 of the array substrate 10, by making the thickness h51 of the second data line 51 (i.e., the dimension of the second data line 51 along the third direction Z) and the thickness hs of the source contact portion s (i.e., the dimension of the source contact portion s along the third direction Z) equal, when the second conductive layer 5 of the array substrate 10 is formed, the thickness h5 of a portion of the second conductive layer 5 in a region corresponding to the second data line 51 (i.e., a dimension of this portion of the second conductive layer 5 along the third direction Z) and the thickness h5 of a portion of the second conductive layer 5 in a region corresponding to the source contact portion s (i.e., a dimension of this portion of the second conductive layer 5 along the third direction Z) are uniform, which is conducive to simplifying the manufacturing process of the second conductive layer 5, which in turn simplifies the manufacturing process of the array substrate 10.

For example, with continuous reference to FIG. 14, the thickness h51 of the second data line 51 in the second conductive layer 5 of the array substrate 10 (i.e., the dimension of the second data line 51 along the third direction Z) may range from 3,000 angstroms to 8,000 angstroms.

For example, the thickness h51 of the second data line 51 in the second conductive layer 5 of the array substrate 10 (i.e., the dimension of the second data line 51 along the third direction Z) may be 3,000 angstroms, 3,500 angstroms, 4,000 angstroms, 4,500 angstroms, 5,000 angstroms, 5,500 angstroms, 6,000 angstroms, 6,500 angstroms, 7,000 angstroms, 7,500 angstroms, or 8,000 angstroms.

With continuous reference to FIG. 14, since in a case where the thickness hs of the source contact portion s in the second conductive layer 5 of the array substrate 10 (i.e., the dimension of the source contact portion s along the third direction Z) is less than the thickness h2 of the first conductive layer 2 of the array substrate 10 (i.e., the dimension of the first conductive layer 2 along the third direction Z), if the thickness hs of the source contact portion s in the second conductive layer 5 of the array substrate 10 (i.e., the dimension of the source contact portion s along the third direction Z) ranges from 3,000 angstroms to 6,000 angstroms, and the thickness h51 of the second data line 51 in the second conductive layer 5 of the array substrate 10 (i.e., the dimension of the second data line 51 along the third direction Z) and the thickness hs of the source contact portion s in the second conductive layer 5 (i.e., the dimension of the source contact portion s along the third direction Z) are equal, the thickness h51 of the second data line 51 in the second conductive layer 5 of the array substrate 10 (i.e., the dimension of the second data line 51 along the third direction Z) also ranges from 3,000 angstroms to 6,000 angstroms, in the case where the thickness hs of the source contact portion s in the second conductive layer 5 of the array substrate 10 (i.e., the dimension of the source contact portion s along the third direction Z) is less than the thickness h2 of the first conductive layer 2 of the array substrate 10 (i.e., the dimension of the first conductive layer 2 along the third direction Z).

For example, the thickness h51 of the second data line 51 in the second conductive layer 5 of the array substrate 10 (i.e., the dimension of the second data line 51 along the third direction Z) may be 3,000 angstroms, 3,500 angstroms, 4,000 angstroms, 4,500 angstroms, 5,000 angstroms, 5,500 angstroms, or 6,000 angstroms.

In some embodiments, with continuous reference to FIG. 14, the thickness h51 of the second data line 51 in the second conductive layer 5 of the array substrate 10 (i.e., the dimension of the second data line 51 along the third direction Z) and the thickness hd of the drain contact portion d in the second conductive layer 5 (i.e., the dimension of the drain contact portion d along the third direction Z) are equal.

Since the second data line 51 and the drain contact portion d are both located in the second conductive layer 5 of the array substrate 10, by making the thickness h51 of the second data line 51 (i.e., the dimension of the second data line 51 along the third direction Z) and the thickness hd of the drain contact portion d (i.e., the dimension of the drain contact portion d along the third direction Z) equal, when the second conductive layer 5 of the array substrate 10 is formed, the thickness h5 of a portion of the second conductive layer 5 in a region corresponding to the second data line 51 (i.e., a dimension of this portion of the second conductive layer 5 along the third direction Z) and the thickness h5 of a portion of the second conductive layer 5 in a region corresponding to the drain contact portion d (i.e., a dimension of this portion of the second conductive layer 5 along the third direction Z) are uniform, which is conducive to simplifying the manufacturing process of the second conductive layer 5, which in turn simplifies the manufacturing process of the array substrate 10.

The following is a detailed description of embodiments in which the thickness h5 of the second conductive layer 5 of the array substrate 10 (i.e., the dimension of the second conductive layer 5 along the third direction Z) is set non-uniformly.

In some embodiments, with continuous reference to FIG. 15, the second data line 51 in the second conductive layer 5 of the array substrate 10 includes first portions 51a. A first portion 51a of the second data line 51 and a data sub-line 211 in the first conductive layer 2 are arranged opposite to each other in the third direction Z (i.e., the direction perpendicular to the substrate 1).

The thickness h51a of the first portion 51a of the second data line 51 in the second conductive layer 5 is greater than the thickness hs of the source contact portion s (i.e., the dimension of the source contact portion s along the third direction Z). That is, the thickness h51a of the first portion 51a of the second data line 51 in the second conductive layer 5 is relatively large, and the thickness hs of the source contact portion s in the second conductive layer 5 (i.e., the dimension of the source contact portion s along the third direction Z) is relatively small.

It will be noted that the above “thickness of the first portion 51a of the second data line 51” refers to a dimension of the first portion 51a of the second data line 51 along the third direction Z (i.e., the direction perpendicular to the substrate 1). The following description about “the thickness of the first portion 51a of the second data line 51” also follows this description and will not be repeated.

By making the thickness hs of the source contact portion s in the second conductive layer 5 (i.e., the dimension of the source contact portion s along the third direction Z) relatively small, it is conducive to reducing the channel length of the active layer pattern T11 of the thin film transistor T1 in the sub-pixel 9, thereby increasing the on-state current lon of the thin film transistor T1. When the thin film transistor T1 in the sub-pixel 9 is turned on to charge the sub-pixel 9 in the display panel 100, it is conducive to improving the charging efficiency of the sub-pixels 9 in the display panel 100 and reducing the probability of insufficient charging of the sub-pixels 9 in the display panel 100, thereby improving the display effect of the display panel 100 including the array substrate 10.

On this basis, by making the thickness h51a of the first portion 51a of the second data line 51 in the second conductive layer 5 (i.e., the dimension of the first portion 51a of the second data line 51 along the third direction Z) relatively large, the line resistance of the second data line 51 in the second conductive layer 5 may be reduced, and then the resistance-capacitance delay (RC Delay) effect of the second data line 51 in the second conductive layer 5 may be weakened. When the sub-pixel 9 in the display panel 100 is charged using the second data line 51 in the second conductive layer 5, it is conducive to further improving the charging efficiency of the sub-pixels 9 in the display panel 100, and further reducing the probability of insufficient charging of the sub-pixels 9 in the display panel 100, thereby further improving the display effect of the display panel 100 including the array substrate 10.

For example, with continuous reference to FIG. 15, the thickness h51a of the first portion 51a of the second data line 51 in the second conductive layer 5 (i.e., the dimension of the first portion 51a of the second data line 51 along the third direction Z) may range from 6,000 angstroms to 15,000 angstroms.

For example, the thickness h51a of the first portion 51a of the second data line 51 in the second conductive layer 5 (i.e., the dimension of the first portion 51a of the second data line 51 along the third direction Z) may be 6,000 angstroms, 6,500 angstroms, 7,000 angstroms, 7,500 angstroms, 8,000 angstroms, 8,500 angstroms, 9,000 angstroms, 9,500 angstroms, 10,000 angstroms, 10,500 angstroms, 11,000 angstroms, 11,500angstroms, 12,000 angstroms, 12,500 angstroms, 13,000 angstroms, 13,500 angstroms, 14,000 angstroms, 14,500 angstroms, or 15,000 angstroms.

For example, with continuous reference to FIG. 15, along the third direction Z (i.e., the direction perpendicular to the substrate 1), the first portion 51a of the second data line 51 in the second conductive layer 5 may include at least two film layer structures, that is, the first portion 51a of the second data line 51 may be formed by at least two deposition processes.

In some embodiments, with continuous reference to FIG. 15, the second data line 51 in the second conductive layer 5 of the array substrate 10 includes second portions 51b. Onto the substrate 1, an orthographic projection of a second portion 51b of the second data line 51 intersects an orthographic projection of the gate line 22 in the first conductive layer 2, and is non-overlapping with orthographic projections of the data sub-lines 211 in the first conductive layer 2. The thickness h51a of the first portion 51a of the second data line 51 (i.e., the dimension of the first portion 51a of the second data line 51 along the third direction Z) is greater than the thickness h51b of the second portion 51b of the second data line 51. That is, the thickness h51a of the first portion 51a of the second data line 51 (i.e., the dimension of the first portion 51a of the second data line 51 along the third direction Z) is relatively large, and the thickness h51b of the second portion 51b of the second data line 51 is relatively small.

It will be noted that the above “thickness of the second portion 51b of the second data line 51” refers to the dimension of the second portion 51b of the second data line 51 along the third direction Z (i.e., the direction perpendicular to the substrate 1). The following description about “the thickness of the second portion 51b of the second data line 51” also follows this description and will not be repeated.

Since onto the substrate 1, the orthographic projection of the second portion 51b of the second data line 51 intersects the orthographic projection of the gate line 22 in the first conductive layer 2, a climbing region exists in the second portion 51b of the second data line 51. By making the thickness h51b of the second portion 51b of the second data line 51 (i.e., the dimension of the second portion 51b of the second data line 51 along the third direction Z) relatively small, when the second data line 51 is formed by an etching process, the etching time is relatively short, which may reduce the probability of a break in the climbing region in the second portion 51b of the second data line 51, which is conducive to improving the yield of the array substrate 10.

For example, with continuous reference to FIG. 15, the thickness h51b of the second portion 51b of the second data line 51 in the second conductive layer 5 (i.e., the dimension of the second portion 51b of the second data line 51 along the third direction Z) may range from 3,000 angstroms to 8,000 angstroms.

For example, the thickness h51b of the second portion 51b of the second data line 51 in the second conductive layer 5 (i.e., the dimension of the second portion 51b of the second data line 51 along the third direction Z) may be 3,000 angstroms, 3,500 angstroms, 4,000 angstroms, 4,500 angstroms, 5,000 angstroms, 5,500 angstroms, 6,000 angstroms, 6,500 angstroms, 7,000 angstroms, 7,500 angstroms, or 8,000 angstroms.

In some embodiments, with continuous reference to FIG. 15, the thickness h51b of the second portion 51b of the second data line 51 (i.e., the dimension of the second portion 51b of the second data line 51 along the third direction Z) and the thickness hs of the source contact portion s (i.e., the dimension of the source contact portion s along the third direction Z) may be equal.

The following is a detailed description of the configuration of the thickness h3 of the first insulating layer 3 of the array substrate 10.

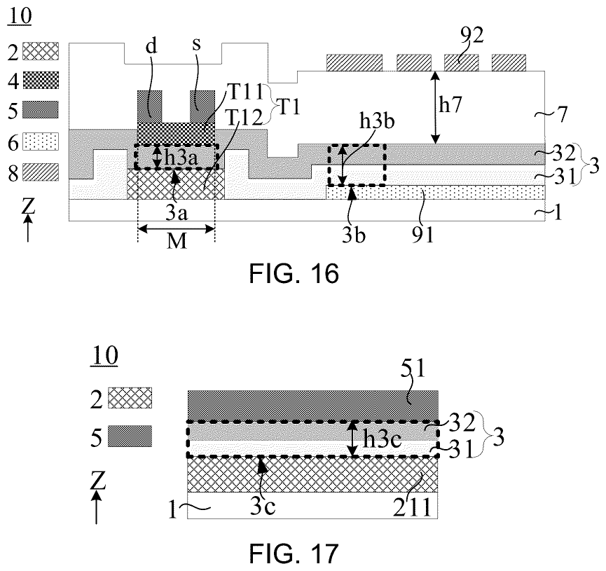

FIG. 16 is a cross-sectional view of a local region of the array substrate 10 in accordance with some embodiments. In some embodiments, as shown in FIG. 16, the first insulating layer 3 of the array substrate 10 includes a first portion 3a and a second portion 3b. The first portion 3a of the first insulating layer 3 is located between the gate pattern T12 of the thin film transistor T1 in the first conductive layer 2 and the active layer pattern T11 of the thin film transistor T1 in the semiconductor layer 4. The second portion 3b of the first insulating layer 3 is located between the pixel electrode 91 in the first electrode layer 6 and the common electrode 92 in the second electrode layer 8. The thickness h3a of the first portion 3a of the first insulating layer 3 is less than the thickness h3b of the second portion 3b of the first insulating layer 3. That is, the thickness h3a of the first portion 3a of the first insulating layer 3 is relatively small, and the thickness h3b of the second portion 3b of the first insulating layer 3 is relatively large.

It will be noted that the above “thickness of the first portion 3a of the first insulating layer 3″ refers to a dimension of the first portion 3a of the first insulating layer 3 along the third direction Z (i.e., the direction perpendicular to the substrate 1), and the above ”thickness of the second portion 3b of the first insulating layer 3″ refers to a dimension of the second portion 3b of the first insulating layer 3 along the third direction Z (i.e., the direction perpendicular to the substrate 1). The following descriptions about “the thickness of the first portion 3a of the first insulating layer 3” and “the thickness of the second portion 3b of the first insulating layer 3” also follow this description and will not be

It can be understood that in a case where the display panel 100 is a thin film transistor liquid crystal display (TFT-LCD) panel, the on-state current lon of the thin film transistor T1 in the display panel 100 is positively correlated with the capacitance of a capacitor formed by the active layer pattern T11 and the gate pattern T12 of the thin film transistor T1, and the first portion 3a of the first insulating layer 3 therebetween. That is, the on-state current lon of the thin film transistor T1 in the display panel 100 increases as the capacitance of the capacitor formed by the active layer pattern T11 and the gate pattern T12 of the thin film transistor T1, and the first portion 3a of the first insulating layer 3 therebetween increases.

The capacitance of the capacitor formed by the active layer pattern T11 and the gate pattern T12 of the thin film transistor T1, and the first portion 3a of the first insulating layer 3 therebetween is negatively correlated with the thickness h3a of the first portion 3a of the first insulating layer 3 (i.e., the dimension of the first portion 3a of the first insulating layer 3 along the third direction Z), that is, the capacitance of the capacitor formed by the active layer pattern T11 and the gate pattern T12 of the thin film transistor T1, and the first portion 3a of the first insulating layer 3 therebetween increases as the thickness h3a of the first portion 3a of the first insulating layer 3 (i.e., the dimension of the first portion 3a of the first insulating layer 3 along the third direction Z) decreases.

By making the thickness h3a of the first portion 3a of the first insulating layer 3 between the gate pattern T12 of the thin film transistor T1 in the first conductive layer 2 and the active layer pattern T11 of the thin film transistor T1 in the semiconductor layer 4 (i.e., the dimension of the first portion 3a of the first insulating layer 3 along the third direction Z) relatively small, the capacitance of the capacitor formed by the active layer pattern T11 and the gate pattern T12 of the thin film transistor T1, and the first portion 3a of the first insulating layer 3 therebetween may be made relatively large, thereby increasing the on-state current lon of the thin film transistor T1. When the thin film transistor T1 in the sub-pixel 9 is turned on to charge the sub-pixel 9 in the display panel 100, it is conducive to improving the charging efficiency of the sub-pixels 9 in the display panel 100 and reducing the probability of insufficient charging of the sub-pixels 9 in the display panel 100, thereby improving the display effect of the display panel 100 including the array substrate 10.

It can be understood that since the second portion 3b of the first insulating layer 3 in the array substrate 10 is located between the pixel electrode 91 in the first electrode layer 6 and the common electrode 92 in the second electrode layer 8, the pixel capacitance jointly formed by the pixel electrode 91 and the common electrode 92 in the sub-pixel 9 is negatively correlated with the thickness h3b of the second portion 3b of the first insulating layer 3 (i.e., the dimension of the second portion 3b of the first insulating layer 3 along the third direction Z), that is, the pixel capacitance jointly formed by the pixel electrode 91 and the common electrode 92 in the sub-pixel 9 of the display panel 100 decreases as the thickness h3b of the second portion 3b of the first insulating layer 3 (i.e., the dimension of the second portion 3b of the first insulating layer 3 along the third direction Z) increases.

By making the thickness h3b of the second portion 3b of the first insulating layer 3 between the pixel electrode 91 in the first electrode layer 6 and the common electrode 92 in the second electrode layer 8 (i.e., the dimension of the second portion 3b of the first insulating layer 3 along the third direction Z) relatively large, the pixel capacitance jointly formed by the pixel electrode 91 and the common electrode 92 in the sub-pixel 9 of the display panel 100 may be made relatively small. When the sub-pixel 9 in the display panel 100 is charged, it is conducive to shortening the charging time of the sub-pixels 9 in the display panel 100 and reducing the probability of insufficient charging of the sub-pixels 9 in the display panel 100, thereby improving the display effect of the display panel 100 including the array substrate 10.

For example, with continuous reference to FIG. 16, the thickness h3a of the first portion 3a of the first insulating layer 3 (i.e., the dimension of the first portion 3a of the first insulating layer 3 along the third direction Z) may range from 2,500 angstroms to 4,000 angstroms.

For example, the thickness h3a of the first portion 3a of the first insulating layer 3 (i.e., the dimension of the first portion 3a of the first insulating layer 3 along the third direction Z) may be 2,500 angstroms, 2,600 angstroms, 2,700 angstroms, 2,800 angstroms, 2,900 angstroms, 3,000 angstroms, 3,100 angstroms, 3,200 angstroms, 3,300 angstroms, 3,400 angstroms, 3,500 angstroms, 3,600 angstroms, 3,700 angstroms, 3,800 angstroms, 3,900 angstroms, or 4,000 angstroms.

For example, with continuous reference to FIG. 16, the thickness h3b of the second portion 3b of the first insulating layer 3 (i.e., the dimension of the second portion 3b of the first insulating layer 3 along the third direction Z) may range from 4,000 angstroms to 5,500 angstroms.

For example, the thickness h3b of the second portion 3b of the first insulating layer 3 (i.e., the dimension of the second portion 3b of the first insulating layer 3 along the third direction Z) may be 4,000 angstroms, 4,100 angstroms, 4,200 angstroms, 4,300 angstroms, 4,400 angstroms, 4,500 angstroms, 4,600 angstroms, 4,700 angstroms, 4,800 angstroms, 4,900 angstroms, 5,000 angstroms, 5,100 angstroms, 5,200 angstroms, 5,300 angstroms, 5,400 angstroms, or 5,500 angstroms.

FIG. 17 is a cross-sectional view of a local region of the array substrate 10 in accordance with some embodiments. In some embodiments, as shown in FIG. 17, and in combination with FIG. 16, the first insulating layer 3 of the array substrate 10 further includes a third portion 3c. The third portion 3c of the first insulating layer 3 is located between the data sub-line 211 in the first conductive layer 2 and the second data line 51 in the second conductive layer 5.

The thickness h3c of the third portion 3c of the first insulating layer 3 is greater than the thickness h3a of the first portion 3a of the first insulating layer 3 (i.e., the dimension of the first portion 3a of the first insulating layer 3 along the third direction Z). That is, the thickness h3c of the third portion 3c of the first insulating layer 3 is relatively large, and the thickness h3a of the first portion 3a of the first insulating layer 3 (i.e., the dimension of the first portion 3a of the first insulating layer 3 along the third direction Z) is relatively small.

It will be noted that the above “thickness of the third portion 3c of the first insulating layer 3” refers to the dimension of the third portion 3c of the first insulating layer 3 along the third direction Z (i.e., the direction perpendicular to the substrate 1). The following description about “the thickness of the third portion 3c of the first insulating layer 3” also follows this description and will not be repeated.

It can be understood that the parasitic capacitance formed between the data sub-line 211 in the first conductive layer 2 and the second data line 51 in the second conductive layer 5 is negatively correlated with the thickness h3c of the third portion 3c of the first insulating layer 3 located between the data sub-line 211 in the first conductive layer 2 and the second data line 51 in the second conductive layer 5 (i.e., the dimension of the third portion 3c of the first insulating layer 3 along the third direction Z). That is, the parasitic capacitance formed between the data sub-line 211 in the first conductive layer 2 and the second data line 51 in the second conductive layer 5 decreases as the thickness h3c of the third portion 3c of the first insulating layer 3 (i.e., the dimension of the third portion 3c of the first insulating layer 3 along the third direction Z) increases.

By making the thickness h3c of the third portion 3c of the first insulating layer 3 between the data sub-line 211 in the first conductive layer 2 and the second data line 51 in the second conductive layer 5 (i.e., the dimension of the third portion 3c of the first insulating layer 3 along the third direction Z) relatively large, in an aspect, the parasitic capacitance formed between the data sub-line 211 in the first conductive layer 2 and the second data line 51 in the second conductive layer 5 may be reduced, and then the resistance-capacitance delay (RC Delay) effect of the data line formed by the first data line 21 in the first conductive layer 2 and the second data line 51 in the second conductive layer 5 may be further weakened, which is conducive to improving the charging efficiency of the sub-pixels 9 in the display panel 100, and reducing the probability of insufficient charging of the sub-pixels 9 in the display panel 100, thereby improving the display effect of the display panel 100 including the array substrate 10.

In another aspect, since the thickness h3c of the third portion 3c of the first insulating layer 3 between the data sub-line 211 in the first conductive layer 2 and the second data line 51 in the second conductive layer 5 (i.e., the dimension of the third portion 3c of the first insulating layer 3 along the third direction Z) is relatively large, it is conducive to improving the insulation performance of the third portion 3c of the first insulating layer 3, which may avoid an electrical breakdown of the third portion 3c of the first insulating layer 3, thereby reducing the probability of the electrical breakdown of the first insulating layer 3, so as to reduce the probability of short circuit between the gate line 22 in the first conductive layer 2 and the second data line 51 in the second conductive layer 5, i.e., to reduce the probability of the data-gate short (DGS) defect in the array substrate 10, which is conducive to improving the yield of the array substrate 10.

For example, with continuous reference to FIG. 17, the thickness h3c of the third portion 3c of the first insulating layer 3 (i.e., the dimension of the third portion 3c of the first insulating layer 3 along the third direction Z) may range from 4000 angstroms to 5500 angstroms.

For example, the thickness h3c of the third portion 3c of the first insulating layer 3 (i.e., the dimension of the third portion 3c of the first insulating layer 3 along the third direction Z) may be 4,000 angstroms, 4,100 angstroms, 4,200 angstroms, 4,300 angstroms, 4,400 angstroms, 4,500 angstroms, 4,600 angstroms, 4,700 angstroms, 4,800 angstroms, 4,900 angstroms, 5,000 angstroms, 5,100 angstroms, 5,200 angstroms, 5,300 angstroms, 5,400 angstroms, or 5,500 angstroms.

In some embodiments, with continuous reference to FIG. 16, the first insulating layer 3 of the array substrate 10 includes a first sub-layer 31 and a second sub-layer 32 which are arranged in a stack.

The gate pattern T12 of the thin film transistor T1 in the first conductive layer 2 and the active layer pattern T11 of the thin film transistor T1 in the semiconductor layer 4 have an overlapping region M in the third direction Z (i.e., the direction perpendicular to the substrate 1), and the overlapping region M is non-overlapping with the first sublayer 31 in the first insulating layer 3. That is, the first sub-layer 31 in the first insulating layer 3 is not located between the gate pattern T12 of the thin film transistor T1 in the first conductive layer 2 and the active layer pattern T11 of the thin film transistor T1 in the semiconductor layer 4.

A portion of the second sub-layer 32 in the first insulating layer 3 is located between the gate pattern T12 of the thin film transistor T1 in the first conductive layer 2 and the active layer pattern T11 of the thin film transistor T1 in the semiconductor layer 4. That is, the gate pattern T12 of the thin film transistor T1 in the first conductive layer 2 and the active layer pattern T11 of the thin film transistor T1 in the semiconductor layer 4 is provided therebetween with a portion of the second sub-layer 32 in the first insulating layer 3.

For example, with continuous reference to FIG. 16, the first sub-layer 31 in the first insulating layer 3 may be closer to the substrate 1 than the second sub-layer 32 in the first insulating layer 3.

For example, a material of the second sub-layer 32 in the first insulating layer 3 may include amorphous silicon.

The following describes in detail the arrangement of the thickness h7 of the second insulating layer 7 of the array substrate 10.

In some embodiments, with continuous reference to FIG. 16, the thickness h7 of the second insulating layer 7 of the array substrate 10 is greater than or equal to 6,000 angstroms and less than or equal to 9,000 angstroms.

It will be noted that the above “thickness of the second insulating layer 7” refers to a dimension of the second insulating layer 7 along the third direction Z (i.e., the direction perpendicular to the substrate 1). The following description about “the thickness of the second insulating layer 7” also follows this description and will not be repeated.

With continuous reference to FIG. 16, in a case where the first portion 3a of the first insulating layer 3 is located between the gate pattern T12 of the thin film transistor T1 in the first conductive layer 2 and the active layer pattern T11 of the thin film transistor T1 in the semiconductor layer 4, the second portion 3b of the first insulating layer 3 is located between the pixel electrode 91 in the first electrode layer 6 and the common electrode 92 in the second electrode layer 8, and the thickness h3a of the first portion 3a of the first insulating layer 3 is less than the thickness h3b of the second portion 3b of the first insulating layer 3, that is, the thickness h3a of the first portion 3a of the first insulating layer 3 is relatively small and the thickness h3b of the second portion 3b of the first insulating layer 3 is relatively large, since the second portion 3b of the first insulating layer 3 and a partial region of the second insulating layer 7 in the array substrate 10 are both located between the pixel electrode 91 in the first electrode layer 6 and the common electrode 92 in the second electrode layer 8, the sum of the thickness h3b of the second portion 3b of the first insulating layer 3 (i.e., the dimension of the second portion 3b of the first insulating layer 3 along the third direction Z) and the thickness h7 of the second insulating layer 7 (i.e., the dimension of the second insulating layer 7 along the third direction Z) is negatively correlated with the pixel capacitance jointly formed by the pixel electrode 91 and the common electrode 92 in the sub-pixel 9, that is, the pixel capacitance jointly formed by the pixel electrode 91 and the common electrode 92 in the sub-pixel 9 of the display panel 100 decreases with the increase of the sum of the thickness h3b of the second portion 3b of the first insulating layer 3 (i.e., the dimension of the second portion 3b of the first insulating layer 3 along the third direction Z) and the thickness h7 of the second insulating layer 7 (i.e., the dimension of the second insulating layer 7 along the third direction Z).

Under the condition that the pixel capacitance jointly formed by the pixel electrode 91 and the common electrode 92 in the sub-pixel 9 of the display panel 100 is small, when the sub-pixel 9 in the display panel 100 is charged, the charging time of the sub-pixel 9 in the display panel 100 is short, and the probability of insufficient charging of the sub-pixel 9 in the display panel 100 is low, if the thickness h3b of the second portion 3b of the first insulating layer 3 is relatively large, the thickness h7 of the second insulating layer 7 (i.e., the dimension of the second insulating layer 7 along the third direction Z) may be appropriately reduced.

By reducing the thickness h7 of the second insulating layer 7 (i.e., the dimension of the second insulating layer 7 along the third direction Z), in an aspect, it is conducive to improving the yield of the second insulating layer 7 and reducing the process difficulty when forming the second insulating layer 7.

In another aspect, with continuous reference to FIG. 16, and in combination with FIG. 12, in a case where the source contact portion s or the drain contact portion d in the second conductive layer 5, the third transfer pattern a3 in the second electrode layer 8 and the pixel electrode 91 in the first electrode layer 6 in the array substrate 10 are connected through the sixth connection portion L6, and the sixth connection portion L6 penetrates the first insulating layer 3 and the second insulating layer 7 of the array substrate 10, by reducing the thickness h7 of the second insulating layer 7 (i.e., the dimension of the second insulating layer 7 along the third direction Z), when the sixth connection portion L6 is formed, the etching path may be shortened and the difficulty of the etching process may be reduced, which is conducive to improving the connection reliability when the source contact portion s or the drain contact portion d in the second conductive layer 5, the third transfer pattern a3 in the second electrode layer 8 and the pixel electrode 91 in the first electrode layer 6 in the array substrate 10 are connected through the sixth connection portion L6, and the resistance of the sixth connection portion L6 may also be reduced.

For example, with continuous reference to FIG. 16, the thickness h7 of the second insulating layer 7 in the array substrate 10 (i.e., the dimension of the second insulating layer 7 along the third direction Z) may be 6,000 angstroms, 6,500 angstroms, 7,000 angstroms, 7,500 angstroms, 8,000 angstroms, 8,500 angstroms, or 9,000 angstroms.

Some embodiments of the present application are described here in combination with FIG. 7A to FIG. 17 regarding the arrangement and connection method of the second data line 51 in the second conductive layer 5 and the plurality of data sub-lines 211 included in the first data line 21 in the first conductive layer 2, the connection method of the pixel electrode 91 in the first electrode layer 6 and the source contact portion s or the drain contact portion d, the setting method of the thickness hs of the source contact portion s in the second conductive layer 5, the thickness hd of the drain contact portion d, and the thickness h51 of the second data line 51 in the second conductive layer 5, the setting method of the thickness h2 of the first conductive layer 2, the setting method of the thickness h3 of the first insulating layer 3, and the setting method of the thickness h7 of the second insulating layer 7 of the array substrate 10. However, the above description of these embodiments of the present application in combination with FIG. 7A to FIG. 17 is exemplary and not exhaustive, and therefore the content is not limited to the disclosed embodiments. Without departing from the scope of the above embodiments, many changes and alterations will be apparent to those skilled in the art.

Specifically, in the embodiments illustrated in FIG. 7A to FIG. 17, for the arrangement and connection method of the second data line 51 in the second conductive layer 5 and the plurality of data sub-lines 211 included in the first data line 21 in the first conductive layer 2, the connection method of the pixel electrode 91 in the first electrode layer 6 and the source contact portion s or the drain contact portion d, the setting method of the thickness hs of the source contact portion s in the second conductive layer 5, the thickness hd of the drain contact portion d, and the thickness h51 of the second data line 51 in the second conductive layer 5, the setting method of the thickness h2 of the first conductive layer 2, the setting method of the thickness h3 of the first insulating layer 3, and the setting method of the thickness h7 of the second insulating layer 7 of the array substrate 10, these settings can all be arbitrarily combined, and any combination of the above embodiments is within the protection scope of the present application.

The foregoing description is only specific embodiments of the present disclosure, but the scope of protection of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. An array substrate, comprising:
a substrate;
a first conductive layer located on the substrate, the first conductive layer comprising gate lines and first data lines, wherein the gate lines extend along a first direction; a first data line in the first data lines comprises a plurality of data sub-lines extending along a second direction, and the plurality of data sub-lines are arranged at intervals along the second direction, the first direction intersecting the second direction; and a gate line in the gate lines passes between two adjacent data sub-lines and is spaced from the two adjacent data sub-lines; and
a second conductive layer located on a side of the first conductive layer away from the substrate, the second conductive layer comprising second data lines extending along the second direction, wherein a second data line in the second data lines is connected in parallel to the plurality of data sub-lines comprised in the first data line.

2. The array substrate according to claim 1, further comprising:
a plurality of thin film transistors; and
a semiconductor layer located between the first conductive layer and the second conductive layer, the semiconductor layer comprising active layer patterns of the plurality of thin film transistors, wherein
the second conductive layer further comprises source contact portions and drain contact portions, and a source contact portion in the source contact portions and a drain contact portion in the drain contact portions are connected to an active layer pattern in the active layer patterns; and
a thickness of the source contact portion and a thickness of the drain contact portion are both less than a thickness of the first conductive layer.

3. The array substrate according to claim 2, wherein a thickness of the second data line is equal to the thickness of the source contact portion.

4. The array substrate according to claim 2, wherein the second data line comprises first portions, and a first portion in the first portions of the second data line is disposed opposite to a data sub-line in the plurality of data sub-lines in a direction perpendicular to the substrate; and
a thickness of the first portion of the second data line is greater than the thickness of the source contact portion.

5. The array substrate according to claim 4, wherein the second data line further comprises second portions; and onto the substrate, an orthographic projection of a second portion in the second portions of the second data line intersects an orthographic projection of the gate line and is non-overlapping with orthographic projections of the plurality of data sub-lines; and
the thickness of the first portion of the second data line is greater than a thickness of the second portion of the second data line.

6. The array substrate according to claim 5, wherein the thickness of the second portion of the second data line is equal to the thickness of the source contact portion.

7. The array substrate according to claim 1, wherein onto the substrate, orthographic projections of the plurality of data sub-lines comprised in the first data line at least partially overlap with an orthographic projection of the second data line.

8. The array substrate according to claim 7, further comprising:
a first insulating layer located between the first conductive layer and the second conductive layer; and
first connection portions penetrating the first insulating layer, wherein two ends of a first connection portion in the first connection portions are connected to a data sub-line in the plurality of data sub-lines and the second data line, respectively.

9. The array substrate according to claim 8, wherein onto the substrate, an orthographic projection of the first connection portion is located within a range of at least one of orthographic projections of the data sub-line and the second data line.

10. The array substrate according to claim 8, further comprising:
a first electrode layer located on a side of the second conductive layer proximate to the substrate, the first electrode layer comprising pixel electrodes; and
second connection portions penetrating the first insulating layer, wherein the second conductive layer further comprises source contact portions and drain contact portions; and for a second connection portion in the second connection portions, one end thereof is connected to a source contact portion in the source contact portions or a drain contact portion in the drain contact portions, and the other end thereof is connected to a pixel electrode in the pixel electrodes.

11. The array substrate according to claim 7, further comprising:
a first electrode layer located on a side of the second conductive layer proximate to the substrate, the first electrode layer comprising first transfer patterns, wherein a first transfer pattern in the first transfer patterns is connected to a data sub-line in the plurality of data sub-lines;
a second electrode layer located on a side of the second conductive layer away from the substrate, the second electrode layer comprising second transfer patterns; and
third connection portions, wherein a second transfer pattern in the second transfer patterns, the second data line and the first transfer pattern are all connected to a third connection portion in the third connection portions.

12. The array substrate according to claim 11, wherein the first transfer pattern overlaps and is in contact with the data sub-line.

13. The array substrate according to claim 11, wherein the first electrode layer further comprises pixel electrodes;
the second electrode layer further comprises third transfer patterns; and
the second conductive layer further comprises source contact portions and drain contact portions, wherein a source contact portion in the source contact portions or a drain contact portion in the drain contact portions is connected to a pixel electrode in the pixel electrodes through a third transfer pattern in the third transfer patterns.

14. The array substrate according to claim 1, further comprising:
a second electrode layer located on a side of the second conductive layer away from the substrate, the second electrode layer comprising fourth transfer patterns; and
fourth connection portions and fifth connection portions, wherein a data sub-line in the plurality of data sub-lines is connected to a fourth transfer pattern in the plurality of data sub-lines through a fourth connection portion in the fourth connection portions, and the second data line is connected to the fourth transfer pattern through a fifth connection portion in the fifth connection portions.

15. The array substrate according to claim 1, wherein the two adjacent data sub-lines in the second direction are provided therebetween with at least one of the gate lines.

16. The array substrate according to claim 1, further comprising:
a plurality of thin film transistors, wherein the first conductive layer comprises gate patterns of the plurality of thin film transistors;
a first electrode layer located on a side of the first conductive layer proximate to the substrate, the first electrode layer comprising pixel electrodes;
a second electrode layer located on a side of the second conductive layer away from the substrate, the second electrode layer comprising common electrodes, wherein a pixel electrode in the pixel electrodes is disposed opposite to a common electrode in the common electrodes in a direction perpendicular to the substrate;
a semiconductor layer located between the first conductive layer and the second conductive layer, the semiconductor layer comprising active layer patterns of the plurality of thin film transistors; and
a first insulating layer located between the first conductive layer and the semiconductor layer, the first insulating layer comprising a first portion and a second portion, wherein the first portion of the first insulating layer is located between the gate patterns and the active layer patterns, and the second portion of the first insulating layer is located between the pixel electrodes and the common electrodes;
wherein a thickness of the first portion of the first insulating layer is less than a thickness of the second portion of the first insulating layer.

17. The array substrate according to claim 16, wherein the first insulating layer further comprises a third portion located between the plurality of data sub-lines and the second data lines, wherein
a thickness of the third portion of the first insulating layer is greater than the thickness of the first portion of the first insulating layer.

18. The array substrate according to claim 16, wherein the first insulating layer has a first sub-layer and a second sub-layer arranged in a stack, wherein
a gate pattern in the gate patterns and an active layer pattern in the active layer patterns have an overlapping region in the direction perpendicular to the substrate, and the overlapping region is non-overlapping with the first sub-layer; and
a portion of the second sub-layer is located between the gate patterns and the active layer patterns.

19. (canceled)

20. (canceled)

21. A display panel, comprising:
the array substrate according to claim 1;
an opposite substrate disposed opposite to and spaced apart from the array substrate; and
a liquid crystal layer disposed between the array substrate and the opposite substrate.

22. A display apparatus, comprising:
the display panel according to claim 21; and
a driving chip electrically connected to the display panel.
